(19) United States
(12) Patent Application Publication
(10) Pub. No.: US 2026/0277292 A1
(43) Pub. Date: Sep. 17, 2026

(54) INTELLIGENT DETERMINATION OF REQUIRED BATTERY LEVELS FOR BATTERY-OPERATED DEVICES

(71) Applicant: CITRIX SYSTEMS, INC., Fort Lauderdale, FL (US)

(72) Inventors: ZONGPENG QIAO, NANJING (CN); KE XU, NANJING (CN); MIYA ZHAO, NANJING (CN); QIAOFEI ZHU, NANJING (CN)

(21) Appl. No.: 18/873,911

(22) PCT Filed: Sep. 21, 2022
(86) PCT No.: PCT/CN2022/120123

§ 371 Date: Dec. 11, 2024

(51) Int. Cl. G06F 1/3228; G06F 9/451

(52) U.S. Cl. CPC G06F 1/3228; G06F 9/451

(57) ABSTRACT

An example methodology implementing the disclosed techniques can include, by a computing device, collecting information about tasks scheduled for a user in a time period, the time period being later than a current time, and determining a battery-operated device associated with one of the tasks. The method can also include determining a length of time the battery-operated device will be powered on during the time period based on the information collected about the tasks and computing a required battery level for the battery-operated device based on the length of time the battery-operated device will be powered on during the time period and an energy consumption rate of the battery-operated device. The method can also include, responsive to a determination that an actual battery level of the battery-operated device is less than the required battery level, providing a notification of a need to charge the battery-operated device.

### BACKGROUND

Use of battery-operated devices, such as Bluetooth devices, is becoming prevalent. This may be due to the evolution in wireless technology contributing to lower cost and increased comfort and simplicity of operation of such devices. For example, employees or other persons associated with an organization, such as a company, may use various Bluetooth devices, such as wireless headsets and keyboards, in performing their daily tasks. These people may also use the same or other Bluetooth devices in their day-to-day activities outside of work. A common problem with using battery-powered devices is having to regularly charge these devices.

### SUMMARY

This Summary is provided to introduce a selection of concepts in simplified form that are further described below in the Detailed Description. This Summary is not intended to identify key or essential features or combinations of the claimed subject matter, nor is it intended to be used to limit the scope of the claimed subject matter.

It is appreciated herein that keeping battery-powered devices, such as Bluetooth devices, sufficiently charged is extremely important. For example, a user, such as an employee of an organization, may use one or more battery-operated devices (e.g., Bluetooth devices) while performing various tasks throughout the day. If a battery-operated device that is to be used while performing a task is not sufficiently charged, the device may run out of charge and shut down while the user is using the device to perform the task. Some battery-operated devices may provide a notification of their battery level once the battery level reaches a predetermined threshold. If the notification of the low battery level is provided while the user is using the battery-operated device, the user is inconvenienced with having to charge the device and the device may still not be available for use until the battery is charged above a certain level. Even in cases where the notification of the low battery level is provided prior to the user starting a task, the user may not have time to sufficiently charge the battery for use while performing the task.

The present disclosure relates to systems and methods for intelligently determining a required battery level for a battery-operated device that is to be used by a user while performing one or more tasks. The required battery level for the battery-operated device may be determined based on an energy consumption rate of the device and a length of time the device will be powered on during a time period. If it is determined that an actual battery level (i.e., a current battery level) of the battery-operated device is less than the required battery level, a notification can be provided to the user of a need to charge the battery-operated device. The techniques described herein can be used to improve the efficiency and utility of existing battery-operated devices, such as Bluetooth devices connected to computing devices. For example, disclosed embodiments can significantly reduce the amount of time that a battery-operated device may be shut down and unavailable due to insufficient battery level.

In accordance with one example embodiment provided to illustrate the broader concepts, systems, and techniques described herein, a method includes, by a computing device, collecting, from one or more task management services, information about tasks scheduled for a user in a time period, the time period being later than a current time, and determining a battery-operated device associated with one of the tasks. The method also includes, by the computing device, determining a length of time the battery-operated device will be powered on during the time period based on the information collected about the tasks and computing a required battery level for the battery-operated device based on the length of time the battery-operated device will be powered on during the time period and an energy consumption rate of the battery-operated device. The method also includes, by the computing device, responsive to a determination that an actual battery level of the battery-operated device is less than the required battery level, providing a notification of a need to charge the battery-operated device.

In some embodiments, the battery-operated device includes a Bluetooth device. In some embodiments, the time period is a next working day. In some embodiments, the time period is a remaining time in a current day.

In some embodiments, the determining the battery-operated device associated with one of the tasks is based on the information collected about the tasks. In some embodiments, the length of time the battery-operated device will be powered on during the time period is a length of the time period. In some embodiments, the length of time the battery-operated device will be powered on during the time period is a length of time of the tasks in the time period which are associated with the battery-operated device. In some embodiments, the energy consumption rate of the battery-operated device is over one or more durations the battery-operated device is powered on during a day. In some embodiments, the energy consumption rate of the battery-operated device is an average energy consumption rate. In one aspect, the average energy consumption rate of the battery-operated device is an average of most recent 10 average daily energy consumption rates of the battery-operated device.

In some embodiments, the providing the notification including sending a request to another computing device to notify of a need to charge the battery-operated device. In one aspect, the method can also include, by the another computing device, responsive to receiving the request, displaying on a display of the another computing device a notice informing that the actual battery level of the battery-operated device is insufficient for the time period, wherein the notice includes a first user interface (UI) element that can be used to obtain details about the required battery level for the battery-operated device, and a second UI element that can be used to provide a confirmation of a charging of the battery-operated device. In one aspect, the method can further include, by the another computing device, responsive to a determination that the confirmation of the charging of the battery-operated device is not received, determining a mobile device associated with the user and causing the notice informing that the actual battery level of the battery-operated device is insufficient for the time period to display on the mobile device.

In some embodiments, the providing the notification includes displaying, by the computing device, on a display of the computing device a notice informing that the actual battery level of the battery-operated device is insufficient for the time period, wherein the notice includes a first user interface (UI) element that can be used to obtain details about the required battery level for the battery-operated device, and a second UI element that can be used to provide a confirmation of a charging of the battery-operated device.

According to another illustrative embodiment provided to illustrate the broader concepts described herein, a computing device includes a processor and a non-volatile memory storing computer program code that when executed on the processor, causes the processor to execute a process corresponding to the aforementioned method or any described embodiment thereof.

According to another illustrative embodiment provided to illustrate the broader concepts described herein, a non-transitory machine-readable medium encodes instructions that when executed by one or more processors cause a process to be carried out, the process corresponding to the aforementioned method or any described embodiment thereof.

### BRIEF DESCRIPTION OF THE DRAWINGS

The foregoing and other objects, features and advantages will be apparent from the following more particular description of the embodiments, as illustrated in the accompanying drawings in which like reference characters refer to the same parts throughout the different views. The drawings are not necessarily to scale, emphasis instead being placed upon illustrating the principles of the embodiments.

FIG. 1 is a diagram of an illustrative network computing environment in which embodiments of the present disclosure may be implemented.

FIG. 2 is a block diagram illustrating selective components of an example computing device in which various aspects of the disclosure may be implemented, in accordance with an embodiment of the present disclosure.

FIG. 3 is a schematic block diagram of a cloud computing environment in which various aspects of the disclosure may be implemented.

FIG. 4A is a block diagram of an illustrative system in which resource management services may manage and streamline access by clients to resource feeds (via one or more gateway services) and/or software-as-a-service (SaaS) applications.

FIG. 4B is a block diagram showing an illustrative implementation of the system shown in FIG. 4A in which various resource management services as well as a gateway service are located within a cloud computing environment.

FIG. 4C is a block diagram similar to FIG. 4B but in which the available resources are represented by a single box labeled “systems of record,” and further in which several different services are included among the resource management services.

FIG. 5 is a block diagram of an illustrative system for intelligent determination of required battery level for battery-operated devices, in accordance with an embodiment of the present disclosure.

FIG. 6 shows an example of a user interface (UI) for presenting a notification of a need to charge a battery-operated device, in accordance with an embodiment of the present disclosure.

FIG. 7 shows an example of a user interface (UI) for presenting additional details regarding a notification of a need to charge a battery-operated device, in accordance with an embodiment of the present disclosure.

FIG. 8 is a flow diagram of an illustrative process for computing an energy consumption rate of a battery-operated device for a recorded duration, in accordance with an embodiment of the present disclosure.

FIG. 9 is a flow diagram of an illustrative process for computing an energy consumption rate of a battery-operated device, in accordance with an embodiment of the present disclosure.

FIG. 10 is a flow diagram of an illustrative process for determining whether a battery-operated device requires charging based on scheduled tasks, in accordance with an embodiment of the present disclosure.

FIG. 11 is a flow diagram of an illustrative process for determining whether a battery-operated device requires charging, in accordance with an embodiment of the present disclosure.

FIG. 12 is a flow diagram of an illustrative process for providing a reminder notification of a need to charge a battery-operated device, in accordance with an embodiment of the present disclosure.

### DETAILED DESCRIPTION

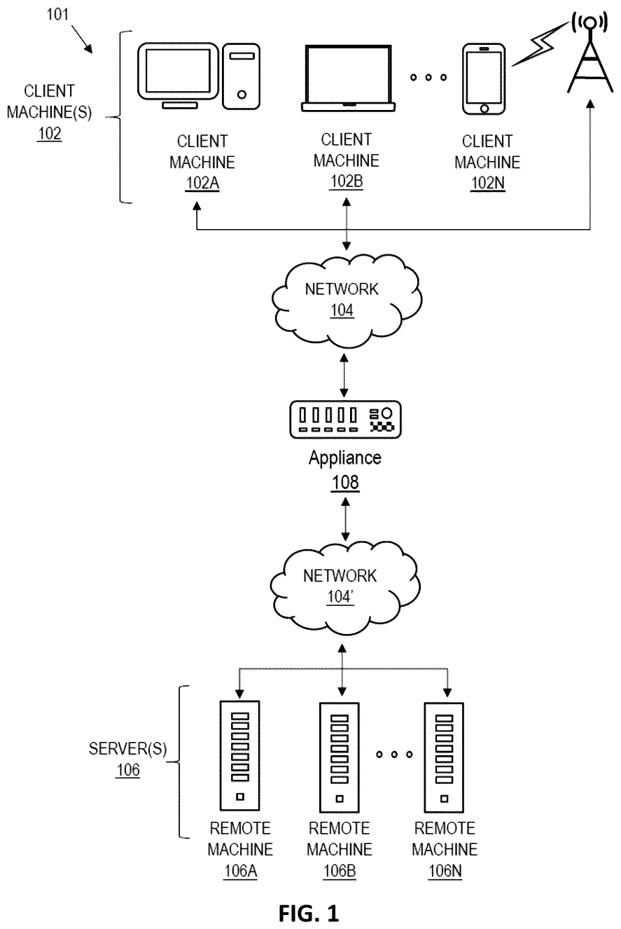

Referring now to FIG. 1, shown is an illustrative network environment 101 of computing devices in which various aspects of the disclosure may be implemented, in accordance with an embodiment of the present disclosure. As shown, environment 101 includes one or more client machines 102A-102N, one or more remote machines 106A-106N, one or more networks 104, 104′, and one or more appliances 108 installed within environment 101. Client machines 102A-102N communicate with remote machines 106A-106N via networks 104, 104′.

In some embodiments, client machines 102A-102N communicate with remote machines 106A-106N via an intermediary appliance 108. The illustrated appliance 108 is positioned between networks 104, 104′ and may also be referred to as a network interface or gateway. In some embodiments, appliance 108 may operate as an application delivery controller (ADC) to provide clients with access to business applications and other data deployed in a datacenter, a cloud computing environment, or delivered as Software as a Service (SaaS) across a range of client devices, and/or provide other functionality such as load balancing, etc. In some embodiments, multiple appliances 108 may be used, and appliance(s) 108 may be deployed as part of network 104 and/or 104′.

Client machines 102A-102N may be generally referred to as client machines 102, local machines 102, clients 102, client nodes 102, client computers 102, client devices 102, computing devices 102, endpoints 102, or endpoint nodes 102. Remote machines 106A-106N may be generally referred to as servers 106 or a server farm 106. In some embodiments, a client device 102 may have the capacity to function as both a client node seeking access to resources provided by server 106 and as a server 106 providing access to hosted resources for other client devices 102A-102N. Networks 104, 104′ may be generally referred to as a network 104. Networks 104 may be configured in any combination of wired and wireless networks.

Server 106 may be any server type such as, for example: a file server; an application server; a web server; a proxy server; an appliance; a network appliance; a gateway; an application gateway; a gateway server; a virtualization server; a deployment server; a Secure Sockets Layer Virtual Private Network (SSL VPN) server; a firewall; a web server; a server executing an active directory; a cloud server; or a server executing an application acceleration program that provides firewall functionality, application functionality, or load balancing functionality.

Server 106 may execute, operate or otherwise provide an application that may be any one of the following: software; a program; executable instructions; a virtual machine; a hypervisor; a web browser; a web-based client; a client-server application; a thin-client computing client; an ActiveX control; a Java applet; software related to voice over internet protocol (VoIP) communications like a soft IP telephone; an application for streaming video and/or audio; an application for facilitating real-time-data communications; a HTTP client; a FTP client; an Oscar client; a Telnet client; or any other set of executable instructions.

In some embodiments, server 106 may execute a remote presentation services program or other program that uses a thin-client or a remote-display protocol to capture display output generated by an application executing on server 106 and transmit the application display output to client device 102.

In yet other embodiments, server 106 may execute a virtual machine providing, to a user of client device 102, access to a computing environment. Client device 102 may be a virtual machine. The virtual machine may be managed by, for example, a hypervisor, a virtual machine manager (VMM), or any other hardware virtualization technique within server 106.

In some embodiments, network 104 may be: a local-area network (LAN); a metropolitan area network (MAN); a wide area network (WAN); a primary public network; and a primary private network. Additional embodiments may include a network 104 of mobile telephone networks that use various protocols to communicate among mobile devices. For short range communications within a wireless local-area network (WLAN), the protocols may include 802.11, Bluetooth, and Near Field Communication (NFC).

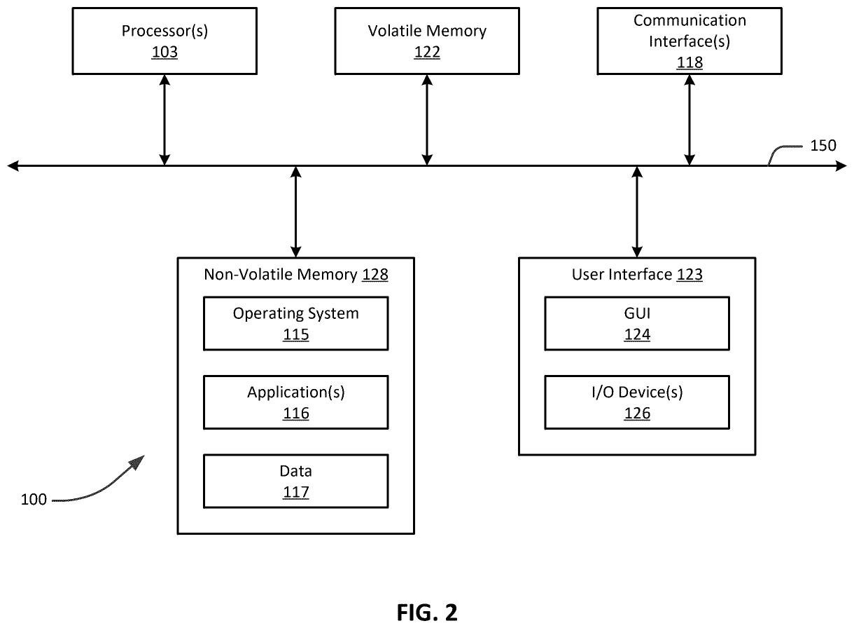

FIG. 2 is a block diagram illustrating selective components of an illustrative computing device 100 in which various aspects of the disclosure may be implemented, in accordance with an embodiment of the present disclosure. For instance, client devices 102, appliances 108, and/or servers 106 of FIG. 1 can be substantially similar to computing device 100. As shown, computing device 100 includes one or more processors 103, a volatile memory 122 (e.g., random access memory (RAM)), a non-volatile memory 128, a user interface (UI) 123, one or more communications interfaces 118, and a communications bus 150.

Non-volatile memory 128 may include: one or more hard disk drives (HDDs) or other magnetic or optical storage media; one or more solid state drives (SSDs), such as a flash drive or other solid-state storage media; one or more hybrid magnetic and solid-state drives; and/or one or more virtual storage volumes, such as a cloud storage, or a combination of such physical storage volumes and virtual storage volumes or arrays thereof.

User interface 123 may include a graphical user interface (GUI) 124 (e.g., a touchscreen, a display, etc.) and one or more input/output (I/O) devices 126 (e.g., a mouse, a keyboard, a microphone, one or more speakers, one or more cameras, one or more biometric scanners, one or more environmental sensors, and one or more accelerometers, etc.).

Non-volatile memory 128 stores an operating system 115, one or more applications 116, and data 117 such that, for example, computer instructions of operating system 115 and/or applications 116 are executed by processor(s) 103 out of volatile memory 122. In some embodiments, volatile memory 122 may include one or more types of RAM and/or a cache memory that may offer a faster response time than a main memory. Data may be entered using an input device of GUI 124 or received from I/O device(s) 126. Various elements of computing device 100 may communicate via communications bus 150.

The illustrated computing device 100 is shown merely as an illustrative client device or server and may be implemented by any computing or processing environment with any type of machine or set of machines that may have suitable hardware and/or software capable of operating as described herein.

Processor(s) 103 may be implemented by one or more programmable processors to execute one or more executable instructions, such as a computer program, to perform the functions of the system. As used herein, the term “processor” describes circuitry that performs a function, an operation, or a sequence of operations. The function, operation, or sequence of operations may be hard coded into the circuitry or soft coded by way of instructions held in a memory device and executed by the circuitry. A processor may perform the function, operation, or sequence of operations using digital values and/or using analog signals.

In some embodiments, the processor can be embodied in one or more application specific integrated circuits (ASICs), microprocessors, digital signal processors (DSPs), graphics processing units (GPUs), microcontrollers, field programmable gate arrays (FPGAs), programmable logic arrays (PLAs), multi-core processors, or general-purpose computers with associated memory.

Processor 103 may be analog, digital or mixed signal. In some embodiments, processor 103 may be one or more physical processors, or one or more virtual (e.g., remotely located or cloud computing environment) processors. A processor including multiple processor cores and/or multiple processors may provide functionality for parallel, simultaneous execution of instructions or for parallel, simultaneous execution of one instruction on more than one piece of data.

Communications interfaces 118 may include one or more interfaces to enable computing device 100 to access a computer network such as a Local Area Network (LAN), a Wide Area Network (WAN), a Personal Area Network (PAN), or the Internet through a variety of wired and/or wireless connections, including cellular connections.

In described embodiments, computing device 100 may execute an application on behalf of a user of a client device. For example, computing device 100 may execute one or more virtual machines managed by a hypervisor. Each virtual machine may provide an execution session within which applications execute on behalf of a user or a client device, such as a hosted desktop session. Computing device 100 may also execute a terminal services session to provide a hosted desktop environment. Computing device 100 may provide access to a remote computing environment including one or more applications, one or more desktop applications, and one or more desktop sessions in which one or more applications may execute.

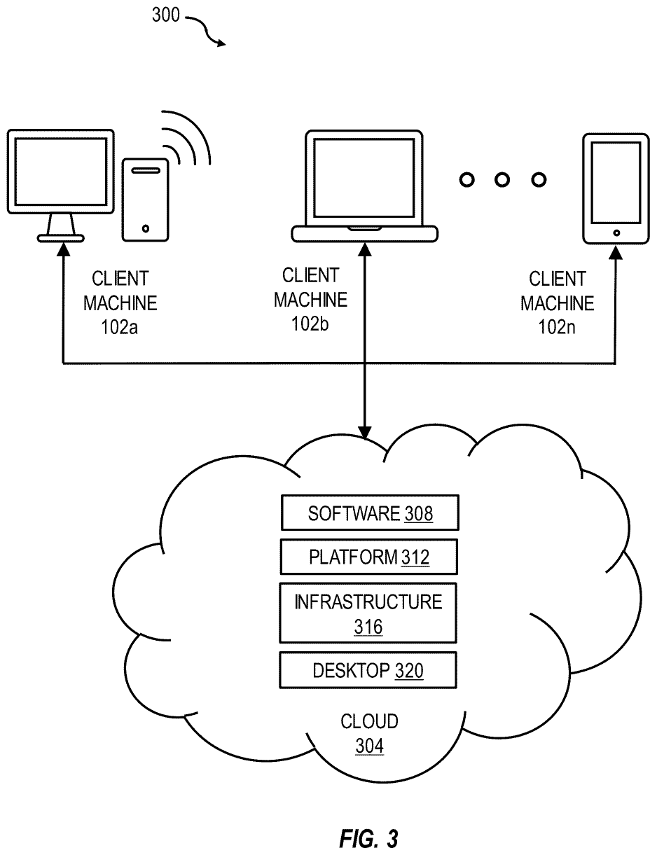

Referring to FIG. 3, a cloud computing environment 300 is depicted, which may also be referred to as a cloud environment, cloud computing or cloud network. Cloud computing environment 300 can provide the delivery of shared computing services and/or resources to multiple users or tenants. For example, the shared resources and services can include, but are not limited to, networks, network bandwidth, servers, processing, memory, storage, applications, virtual machines, databases, software, hardware, analytics, and intelligence.

In cloud computing environment 300, one or more clients 102a-102n (such as those described above) are in communication with a cloud network 304. Cloud network 304 may include back-end platforms, e.g., servers, storage, server farms or data centers. The users or clients 102a-102n can correspond to a single organization/tenant or multiple organizations/tenants. More particularly, in one illustrative implementation, cloud computing environment 300 may provide a private cloud serving a single organization (e.g., enterprise cloud). In another example, cloud computing environment 300 may provide a community or public cloud serving multiple organizations/tenants.

In some embodiments, a gateway appliance(s) or service may be utilized to provide access to cloud computing resources and virtual sessions. By way of example, Citrix Gateway, provided by Citrix Systems, Inc., may be deployed on-premises or on public clouds to provide users with secure access and single sign-on to virtual, SaaS and web applications. Furthermore, to protect users from web threats, a gateway such as Citrix Secure Web Gateway may be used. Citrix Secure Web Gateway uses a cloud-based service and a local cache to check for URL reputation and category.

In still further embodiments, cloud computing environment 300 may provide a hybrid cloud that is a combination of a public cloud and a private cloud. Public clouds may include public servers that are maintained by third parties to clients 102a-102n or the enterprise/tenant. The servers may be located off-site in remote geographical locations or otherwise.

Cloud computing environment 300 can provide resource pooling to serve multiple users via clients 102a-102n through a multi-tenant environment or multi-tenant model with different physical and virtual resources dynamically assigned and reassigned responsive to different demands within the respective environment. The multi-tenant environment can include a system or architecture that can provide a single instance of software, an application or a software application to serve multiple users. In some embodiments, cloud computing environment 300 can provide on-demand self-service to unilaterally provision computing capabilities (e.g., server time, network storage) across a network for multiple clients 102a-102n. By way of example, provisioning services may be provided through a system such as Citrix Provisioning Services (Citrix PVS). Citrix PVS is a software-streaming technology that delivers patches, updates, and other configuration information to multiple virtual desktop endpoints through a shared desktop image. Cloud computing environment 300 can provide an elasticity to dynamically scale out or scale in response to different demands from one or more clients 102. In some embodiments, cloud computing environment 300 can include or provide monitoring services to monitor, control and/or generate reports corresponding to the provided shared services and resources.

In some embodiments, cloud computing environment 300 may provide cloud-based delivery of different types of cloud computing services, such as Software as a service (SaaS) 308, Platform as a Service (PaaS) 312, Infrastructure as a Service (IaaS) 316, and Desktop as a Service (DaaS) 320, for example. IaaS may refer to a user renting the use of infrastructure resources that are needed during a specified time period. IaaS providers may offer storage, networking, servers or virtualization resources from large pools, allowing the users to quickly scale up by accessing more resources as needed. Examples of IaaS include AMAZON WEB SERVICES provided by Amazon.com, Inc., of Seattle, Washington, RACKSPACE CLOUD provided by Rackspace US, Inc., of San Antonio, Texas, Google Compute Engine provided by Google Inc. of Mountain View, California, or RIGHTSCALE provided by RightScale, Inc., of Santa Barbara, California.

PaaS providers may offer functionality provided by IaaS, including, e.g., storage, networking, servers or virtualization, as well as additional resources such as, e.g., the operating system, middleware, or runtime resources. Examples of PaaS include WINDOWS AZURE provided by Microsoft Corporation of Redmond, Washington, Google App Engine provided by Google Inc., and HEROKU provided by Heroku, Inc. of San Francisco, California.

SaaS providers may offer the resources that PaaS provides, including storage, networking, servers, virtualization, operating system, middleware, or runtime resources. In some embodiments, SaaS providers may offer additional resources including, e.g., data and application resources. Examples of SaaS include GOOGLE APPS provided by Google Inc., SALESFORCE provided by Salesforce.com Inc. of San Francisco, California, or OFFICE 365 provided by Microsoft Corporation. Examples of SaaS may also include data storage providers, e.g., Citrix ShareFile from Citrix Systems, DROPBOX provided by Dropbox, Inc. of San Francisco, California, Microsoft SKYDRIVE provided by Microsoft Corporation, Google Drive provided by Google Inc., or Apple ICLOUD provided by Apple Inc. of Cupertino, California.

Similar to SaaS, DaaS (which is also known as hosted desktop services) is a form of virtual desktop infrastructure (VDI) in which virtual desktop sessions are typically delivered as a cloud service along with the apps used on the virtual desktop. Citrix Cloud from Citrix Systems is one example of a DaaS delivery platform. DaaS delivery platforms may be hosted on a public cloud computing infrastructure such as AZURE CLOUD from Microsoft Corporation of Redmond, Washington (herein “Azure”), or AMAZON WEB SERVICES provided by Amazon.com, Inc., of Seattle, Washington (herein “AWS”), for example. In the case of Citrix Cloud, Citrix Workspace app may be used as a single-entry point for bringing apps, files and desktops together (whether on-premises or in the cloud) to deliver a unified experience.

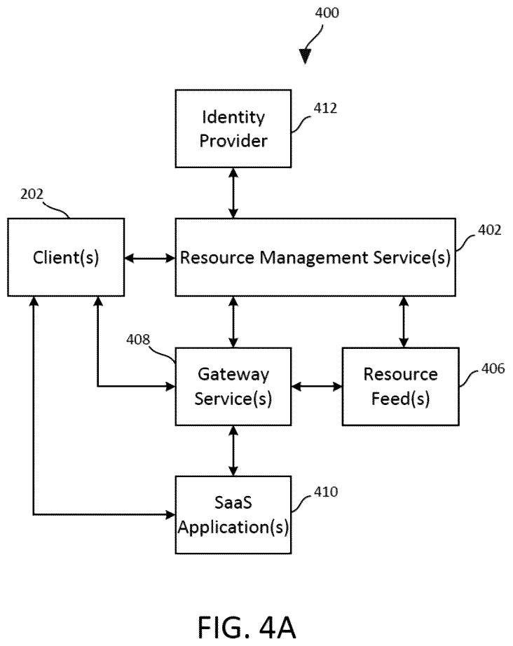

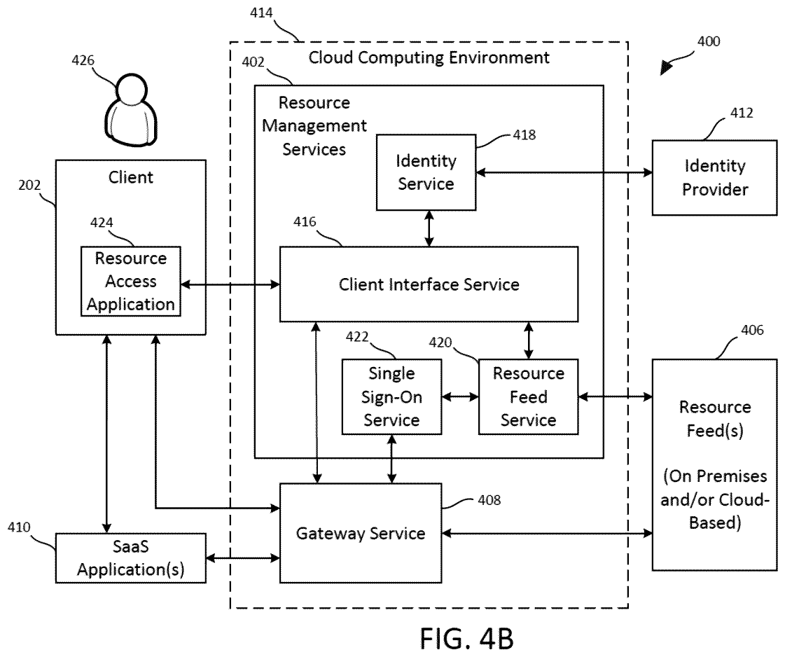

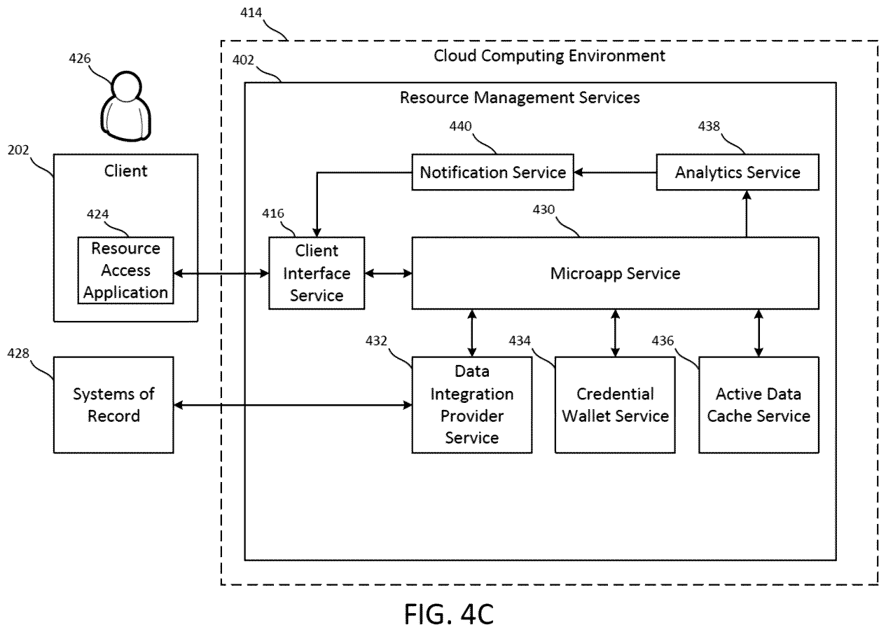

FIG. 4A is a block diagram of an illustrative system 400 in which one or more resource management services 402 may manage and streamline access by one or more clients 202 to one or more resource feeds 406 (via one or more gateway services 408) and/or one or more software-as-a-service (SaaS) applications 410. In particular, resource management service(s) 402 may employ an identity provider 412 to authenticate the identity of a user of a client 202 and, following authentication, identify one of more resources the user is authorized to access. In response to the user selecting one of the identified resources, resource management service(s) 402 may send appropriate access credentials to the requesting client 202, and the requesting client 202 may then use those credentials to access the selected resource. For resource feed(s) 406, client 202 may use the supplied credentials to access the selected resource via gateway service 408. For SaaS application(s) 410, client 202 may use the credentials to access the selected application directly.

Client(s) 202 may be any type of computing devices capable of accessing resource feed(s) 406 and/or SaaS application(s) 410, and may, for example, include a variety of desktop or laptop computers, smartphones, tablets, etc. Resource feed(s) 406 may include any of numerous resource types and may be provided from any of numerous locations. In some embodiments, for example, resource feed(s) 406 may include one or more systems or services for providing virtual applications and/or desktops to client(s) 202, one or more file repositories and/or file sharing systems, one or more secure browser services, one or more access control services for SaaS applications 410, one or more management services for local applications on client(s) 202, one or more internet enabled devices or sensors, etc. Each of resource management service(s) 402, resource feed(s) 406, gateway service(s) 408, SaaS application(s) 410, and identity provider 412 may be located within an on-premises data center of an organization for which system 400 is deployed, within one or more cloud computing environments, or elsewhere.

FIG. 4B is a block diagram showing an illustrative implementation of system 400 shown in FIG. 4A in which various resource management services 402 as well as gateway service 408 are located within a cloud computing environment 414. The cloud computing environment may, for example, include Microsoft Azure Cloud, Amazon Web Services, Google Cloud, or IBM Cloud.

For any of illustrated components (other than client 202) that are not based within cloud computing environment 414, cloud connectors (not shown in FIG. 4B) may be used to interface those components with cloud computing environment 414. Such cloud connectors may, for example, run on Windows Server instances hosted in resource locations and may create a reverse proxy to route traffic between the site(s) and cloud computing environment 414. In the illustrated example, the cloud-based resource management services 402 include a client interface service 416, an identity service 418, a resource feed service 420, and a single sign-on service 422. As shown, in some embodiments, client 202 may use a resource access application 424 to communicate with client interface service 416 as well as to present a user interface on client 202 that a user 426 can operate to access resource feed(s) 406 and/or SaaS application(s) 410. Resource access application 424 may either be installed on client 202 or may be executed by client interface service 416 (or elsewhere in system 400) and accessed using a web browser (not shown in FIG. 4B) on client 202.

As explained in more detail below, in some embodiments, resource access application 424 and associated components may provide user 426 with a personalized, all-in-one interface enabling instant and seamless access to all the user's SaaS and web applications, files, virtual Windows applications, virtual Linux applications, desktops, mobile applications, Citrix Virtual Apps and Desktops™, local applications, and other data.

When resource access application 424 is launched or otherwise accessed by user 426, client interface service 416 may send a sign-on request to identity service 418. In some embodiments, identity provider 412 may be located on the premises of the organization for which system 400 is deployed. Identity provider 412 may, for example, correspond to an on-premises Windows Active Directory. In such embodiments, identity provider 412 may be connected to the cloud-based identity service 418 using a cloud connector (not shown in FIG. 4B), as described above. Upon receiving a sign-on request, identity service 418 may cause resource access application 424 (via client interface service 416) to prompt user 426 for the user's authentication credentials (e.g., username and password). Upon receiving the user's authentication credentials, client interface service 416 may pass the credentials along to identity service 418, and identity service 418 may, in turn, forward them to identity provider 412 for authentication, for example, by comparing them against an Active Directory domain. Once identity service 418 receives confirmation from identity provider 412 that the user's identity has been properly authenticated, client interface service 416 may send a request to resource feed service 420 for a list of subscribed resources for user 426.

In other embodiments (not illustrated in FIG. 4B), identity provider 412 may be a cloud-based identity service, such as a Microsoft Azure Active Directory. In such embodiments, upon receiving a sign-on request from client interface service 416, identity service 418 may, via client interface service 416, cause client 202 to be redirected to the cloud-based identity service to complete an authentication process. The cloud-based identity service may then cause client 202 to prompt user 426 to enter the user's authentication credentials. Upon determining the user's identity has been properly authenticated, the cloud-based identity service may send a message to resource access application 424 indicating the authentication attempt was successful, and resource access application 424 may then inform client interface service 416 of the successfully authentication. Once identity service 418 receives confirmation from client interface service 416 that the user's identity has been properly authenticated, client interface service 416 may send a request to resource feed service 420 for a list of subscribed resources for user 426.

For each configured resource feed, resource feed service 420 may request an identity token from single sign-on service 422. Resource feed service 420 may then pass the feed-specific identity tokens it receives to the points of authentication for the respective resource feeds 406. Each resource feed 406 may then respond with a list of resources configured for the respective identity. Resource feed service 420 may then aggregate all items from the different feeds and forward them to client interface service 416, which may cause resource access application 424 to present a list of available resources on a user interface of client 202. The list of available resources may, for example, be presented on the user interface of client 202 as a set of selectable icons or other elements corresponding to accessible resources. The resources so identified may, for example, include one or more virtual applications and/or desktops (e.g., Citrix Virtual Apps and Desktops™, VMware Horizon, Microsoft RDS, etc.), one or more file repositories and/or file sharing systems (e.g., Sharefile®, one or more secure browsers, one or more internet enabled devices or sensors, one or more local applications installed on client 202, and/or one or more SaaS applications 410 to which user 426 has subscribed. The lists of local applications and SaaS applications 410 may, for example, be supplied by resource feeds 406 for respective services that manage which such applications are to be made available to user 426 via resource access application 424. Examples of SaaS applications 410 that may be managed and accessed as described herein include Microsoft Office 365 applications, SAP SaaS applications, Workday applications, etc.

For resources other than local applications and SaaS application(s) 410, upon user 426 selecting one of the listed available resources, resource access application 424 may cause client interface service 416 to forward a request for the specified resource to resource feed service 420. In response to receiving such a request, resource feed service 420 may request an identity token for the corresponding feed from single sign-on service 422. Resource feed service 420 may then pass the identity token received from single sign-on service 422 to client interface service 416 where a launch ticket for the resource may be generated and sent to resource access application 424. Upon receiving the launch ticket, resource access application 424 may initiate a secure session to gateway service 408 and present the launch ticket. When gateway service 408 is presented with the launch ticket, it may initiate a secure session to the appropriate resource feed and present the identity token to that feed to seamlessly authenticate user 426. Once the session initializes, client 202 may proceed to access the selected resource.

When user 426 selects a local application, resource access application 424 may cause the selected local application to launch on client 202. When user 426 selects SaaS application 410, resource access application 424 may cause client interface service 416 request a one-time uniform resource locator (URL) from gateway service 408 as well a preferred browser for use in accessing SaaS application 410. After gateway service 408 returns the one-time URL and identifies the preferred browser, client interface service 416 may pass that information along to resource access application 424. Client 202 may then launch the identified browser and initiate a connection to gateway service 408. Gateway service 408 may then request an assertion from single sign-on service 422. Upon receiving the assertion, gateway service 408 may cause the identified browser on client 202 to be redirected to the logon page for identified SaaS application 410 and present the assertion. The SaaS may then contact gateway service 408 to validate the assertion and authenticate user 426. Once the user has been authenticated, communication may occur directly between the identified browser and the selected SaaS application 410, thus allowing user 426 to use client 202 to access the selected SaaS application 410.

In some embodiments, the preferred browser identified by gateway service 408 may be a specialized browser embedded in resource access application 424 (when the resource application is installed on client 202) or provided by one of the resource feeds 406 (when resource access application 424 is located remotely), e.g., via a secure browser service. In such embodiments, SaaS applications 410 may incorporate enhanced security policies to enforce one or more restrictions on the embedded browser. Examples of such policies include (1) requiring use of the specialized browser and disabling use of other local browsers, (2) restricting clipboard access, e.g., by disabling cut/copy/paste operations between the application and the clipboard, (3) restricting printing, e.g., by disabling the ability to print from within the browser, (3) restricting navigation, e.g., by disabling the next and/or back browser buttons, (4) restricting downloads, e.g., by disabling the ability to download from within the SaaS application, and (5) displaying watermarks, e.g., by overlaying a screen-based watermark showing the username and IP address associated with client 202 such that the watermark will appear as displayed on the screen if the user tries to print or take a screenshot. Further, in some embodiments, when a user selects a hyperlink within a SaaS application, the specialized browser may send the URL for the link to an access control service (e.g., implemented as one of the resource feed(s) 406) for assessment of its security risk by a web filtering service. For approved URLs, the specialized browser may be permitted to access the link. For suspicious links, however, the web filtering service may have client interface service 416 send the link to a secure browser service, which may start a new virtual browser session with client 202, and thus allow the user to access the potentially harmful linked content in a safe environment.

In some embodiments, in addition to or in lieu of providing user 426 with a list of resources that are available to be accessed individually, as described above, user 426 may instead be permitted to choose to access a streamlined feed of event notifications and/or available actions that may be taken with respect to events that are automatically detected with respect to one or more of the resources. This streamlined resource activity feed, which may be customized for each user 426, may allow users to monitor important activity involving all of their resources-SaaS applications, web applications, Windows applications, Linux applications, desktops, file repositories and/or file sharing systems, and other data through a single interface, without needing to switch context from one resource to another. Further, event notifications in a resource activity feed may be accompanied by a discrete set of user-interface elements, e.g., “approve,” “deny,” and “see more detail” buttons, allowing a user to take one or more simple actions with respect to each event right within the user's feed. In some embodiments, such a streamlined, intelligent resource activity feed may be enabled by one or more micro-applications, or “microapps,” that can interface with underlying associated resources using APIs or the like. The responsive actions may be user-initiated activities that are taken within the microapps and that provide inputs to the underlying applications through the API or other interface. The actions a user performs within the microapp may, for example, be designed to address specific common problems and use cases quickly and easily, adding to increased user productivity (e.g., request personal time off, submit a help desk ticket, etc.). In some embodiments, notifications from such event-driven microapps may additionally or alternatively be pushed to clients 202 to notify user 426 of something that requires the user's attention (e.g., approval of an expense report, new course available for registration, etc.).

FIG. 4C is a block diagram similar to that shown in FIG. 4B but in which the available resources (e.g., SaaS applications, web applications, Windows applications, Linux applications, desktops, file repositories and/or file sharing systems, and other data) are represented by a single box 428 labeled “systems of record,” and further in which several different services are included within the resource management services block 402. As explained below, the services shown in FIG. 4C may enable the provision of a streamlined resource activity feed and/or notification process for client 202. In the example shown, in addition to client interface service 416 discussed above, the illustrated services include a microapp service 430, a data integration provider service 432, a credential wallet service 434, an active data cache service 436, an analytics service 438, and a notification service 440. In various embodiments, the services shown in FIG. 4C may be employed either in addition to or instead of the different services shown in FIG. 4B.

In some embodiments, a microapp may be a single use case made available to users to streamline functionality from complex enterprise applications. Microapps may, for example, utilize APIs available within SaaS, web, or home-grown applications allowing users to see content without needing a full launch of the application or the need to switch context. Absent such microapps, users would need to launch an application, navigate to the action they need to perform, and then perform the action. Microapps may streamline routine tasks for frequently performed actions and provide users the ability to perform actions within resource access application 424 without having to launch the native application. The system shown in FIG. 4C may, for example, aggregate relevant notifications, tasks, and insights, and thereby give user 426 a dynamic productivity tool. In some embodiments, the resource activity feed may be intelligently populated by utilizing machine learning and artificial intelligence (AI) algorithms. Further, in some implementations, microapps may be configured within cloud computing environment 414, thus giving administrators a powerful tool to create more productive workflows, without the need for additional infrastructure. Whether pushed to a user or initiated by a user, microapps may provide short cuts that simplify and streamline key tasks that would otherwise require opening full enterprise applications. In some embodiments, out-of-the-box templates may allow administrators with API account permissions to build microapp solutions targeted for their needs. Administrators may also, in some embodiments, be provided with the tools they need to build custom microapps.

Referring to FIG. 4C, systems of record 428 may represent the applications and/or other resources resource management services 402 may interact with to create microapps. These resources may be SaaS applications, legacy applications, or homegrown applications, and can be hosted on-premises or within a cloud computing environment. Connectors with out-of-the-box templates for several applications may be provided and integration with other applications may additionally or alternatively be configured through a microapp page builder. Such a microapp page builder may, for example, connect to legacy, on-premises, and SaaS systems by creating streamlined user workflows via microapp actions. Resource management services 402, and in particular data integration provider service 432, may, for example, support REST API, JSON, OData-JSON, and 6ML. As explained in more detail below, data integration provider service 432 may also write back to the systems of record, for example, using OAuth2 or a service account.

In some embodiments, microapp service 430 may be a single-tenant service responsible for creating the microapps. Microapp service 430 may send raw events, pulled from systems of record 428, to analytics service 438 for processing. The microapp service may, for example, periodically pull active data from systems of record 428.

In some embodiments, active data cache service 436 may be single-tenant and may store all configuration information and microapp data. It may, for example, utilize a per-tenant database encryption key and per-tenant database credentials.

In some embodiments, credential wallet service 434 may store encrypted service credentials for systems of record 428 and user OAuth2 tokens.

In some embodiments, data integration provider service 432 may interact with systems of record 428 to decrypt end-user credentials and write back actions to systems of record 428 under the identity of the end-user. The write-back actions may, for example, utilize a user's actual account to ensure all actions performed are compliant with data policies of the application or other resource being interacted with.

In some embodiments, analytics service 438 may process the raw events received from microapps service 430 to create targeted scored notifications and send such notifications to notification service 440.

Finally, in some embodiments, notification service 440 may process any notifications it receives from analytics service 438. In some implementations, notification service 440 may store the notifications in a database to be later served in a notification feed. In other embodiments, notification service 440 may additionally or alternatively send the notifications out immediately to client 202 as a push notification to user 426.

In some embodiments, a process for synchronizing with systems of record 428 and generating notifications may operate as follows. Microapp service 430 may retrieve encrypted service account credentials for systems of record 428 from credential wallet service 434 and request a sync with data integration provider service 432. Data integration provider service 432 may then decrypt the service account credentials and use those credentials to retrieve data from systems of record 428. Data integration provider service 432 may then stream the retrieved data to microapp service 430. Microapp service 430 may store the received systems of record data in active data cache service 436 and also send raw events to analytics service 438. Analytics service 438 may create targeted scored notifications and send such notifications to notification service 440. Notification service 440 may store the notifications in a database to be later served in a notification feed and/or may send the notifications out immediately to client 202 as a push notification to user 426.

In some embodiments, a process for processing a user-initiated action via a microapp may operate as follows. Client 202 may receive data from microapp service 430 (via client interface service 416) to render information corresponding to the microapp. Microapp service 430 may receive data from active data cache service 436 to support that rendering. User 426 may invoke an action from the microapp, causing resource access application 424 to send that action to microapp service 430 (via client interface service 416). Microapp service 430 may then retrieve from credential wallet service 434 an encrypted Oauth2 token for the system of record for which the action is to be invoked and may send the action to data integration provider service 432 together with the encrypted Oath2 token. Data integration provider service 432 may then decrypt the Oath2 token and write the action to the appropriate system of record under the identity of user 426. Data integration provider service 432 may then read back changed data from the written-to system of record and send that changed data to microapp service 430. Microapp service 432 may then update active data cache service 436 with the updated data and cause a message to be sent to resource access application 424 (via client interface service 416) notifying user 426 that the action was successfully completed.

In some embodiments, in addition to or in lieu of the functionality described above, resource management services 402 may provide users the ability to search for relevant information across all files and applications. A simple keyword search may, for example, be used to find application resources, SaaS applications, desktops, files, etc. This functionality may enhance user productivity and efficiency as application and data sprawl is prevalent across all organizations.

In other embodiments, in addition to or in lieu of the functionality described above, resource management services 402 may enable virtual assistance functionality that allows users to remain productive and take quick actions. Users may, for example, interact with the “Virtual Assistant” and ask questions such as “What is Bob Smith's phone number?” or “What absences are pending my approval?” Resource management services 402 may, for example, parse these requests and respond because they are integrated with multiple systems on the backend. In some embodiments, users may be able to interact with the virtual assistance through either resource access application 424 or directly from another resource, such as Microsoft Teams. This feature may allow employees to work efficiently, stay organized, and deliver only the specific information they're looking for.

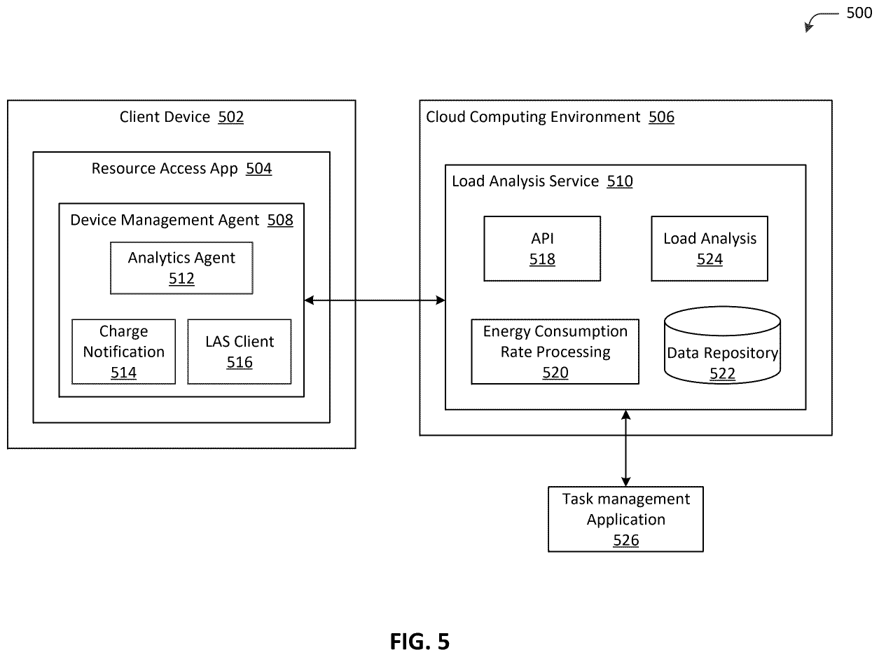

FIG. 5 is a block diagram of an illustrative system 500 for intelligent determination of required battery levels for battery-operated devices, in accordance with an embodiment of the present disclosure. In brief, system 500 can provide a notification of a need to charge a battery-operated device in response to determining that an actual battery level of the device is less than a required battery level for the device. System 500 includes a resource access application 504 installed on a client device 502 and configured to communicate with a cloud computing environment 506 via one or more computer networks. Client device 502, resource access application 504, and cloud computing environment 506 of FIG. 5 can be the same as or similar to client 202, resource access application 424, and cloud computing environment 414, respectively, of FIGS. 4A-4C.

As shown in FIG. 5, a device management agent 508 can be provided as sub-module or other component of resource access application 504. A load analysis service 510 can be provided as a service (e.g., a microservice) within cloud computing environment 506. Device management agent 508 and load analysis service 510 can interoperate to determine a required battery level for a battery-operated device associated with a user and provide a notification of a need to charge the battery-operated device if an actual battery level (i.e., a current battery level) of the battery-operated device is less than (e.g., insufficient for) the required battery level. The required battery level for the battery-operated device may be determined (e.g., predicted) based on the device's historical battery consumption data (e.g., energy consumption rate) and the user's scheduled use of the device.

In some embodiments described herein, the battery-operated devices include devices that are managed by an organization that provides load analysis service 510. In such embodiments, the organization may utilize an enterprise mobility management (EMM) system or other suitable device management system to manage the battery-operated devices. To facilitate management by the organization, the battery-operated devices that are to be managed, including information about the users associated with the battery-operated devices (e.g., information about the users of the battery-operated devices), may be registered with the organization's EMM system. Generally, the managed devices are under the control of the organization and can include both devices that are purchased by the user (e.g., personal battery-operated devices) and devices that are provided by the organization to the user.

To promote clarity in the drawings, FIG. 5 shows a single resource access application 504 communicably coupled to load analysis service 510. However, embodiments of load analysis service 510 can be used to service many resource access applications (e.g., resource access applications 504) installed on clients (e.g., client devices 502) used by many different users associated with one or more organizations. Device management agent 508 and/or load analysis service 510 may be implemented as computer instructions executable to perform the corresponding functions disclosed herein. Device management agent 508 and load analysis service 510 can be logically and/or physically organized into one or more components. In the example of FIG. 5, device management agent 508 includes an analytics agent 512, a charge notification module 514, and a load analysis service (LAS) client 516. Also, in this example, load analysis service 510 includes an application programming interface (API) module 518, an energy consumption rate processing module 520, a data repository 522, and a load analysis module 524.

The client-side device management agent 508 can communicate with the cloud-side load analysis service 510 using an API. For example, device management agent 508 can utilize LAS client 516 to send requests (or “messages”) to load analysis service 510 wherein the requests are received and processed by API module 518 of load analysis service 510. Likewise, load analysis service 510 can utilize API module 518 to send responses/messages to device management agent 508 wherein the responses/messages are received and processed by LAS client 516 of device management agent 508. In some embodiments, load analysis service 510 can push information to device management agent 508.

Referring to the client-side device management agent 508, analytics agent 512 is operable to monitor the battery usage of battery-operated devices, such as Bluetooth devices, connected or otherwise coupled to client device 502 and which are being used by a user of client device 502. Non-limiting examples of battery-operated devices include a mouse, a keyboard, a digital pen, a microphone, a headset, a VR goggle, and a VR controller. Analytics agent 512 may utilize an API provided by the operating system (OS) on client device 512, such as the Bluetoothapis under WIN32 API provided by WINDOWS, to discover (e.g., determine) the battery-operated devices connected to client device 502. Analytics agent 512 may also register with the OS to receive event notification messages when devices (e.g., battery-operated devices) connect to or disconnect from client device 502.

As mentioned previously, analytics agent 512 can monitor the battery usage of battery-operated devices connected to client device 502. Battery usage monitoring can include computing an energy consumption rate (e.g., battery consumption rate) of the individual battery-operated devices connected to client device 502. To compute an energy consumption rate of a particular battery-operated device connected to client device 502, analytics agent 512 can monitor the battery-operated device to detect a power on and a power off of the device. When the battery-operated device is powered on, analytics agent 512 can record the time the device is powered on and the device's current battery level when powered on. For example, for a particular battery-operated device connected to client device 502, analytics agent 512 may utilize an API provided by the OS on client device 502 to determine a current battery level of the battery-operated device. Subsequently, when the battery-operated device is powered off, analytics agent 512 can record the time the device is powered off and the device's current battery level when powered off. Using the recorded times and the recorded battery levels at the recorded times, analytics agent 512 can compute an energy consumption rate of the battery-operated device for the recorded duration as follows:

$$u = \frac{X}{{T}_{off} - {T}_{on}} ,$$

where X is energy usage (e.g., battery usage), T_{off} is the time the device is turned off, Tₒₙ is the time the device was turned on, and u is the per minute energy consumption by the device.

As an example of computing an energy consumption rate of a battery-operated device, suppose that a battery-operated headset is powered on at 10:00 AM and powered off at 11:00 AM. Also suppose that the battery level of the headset is 80% when powered on and 70% when powered off. In this example, when the headset is powered on, analytics agent 512 can record 10:00 AM as the time the headset is powered on and 80% as the battery level of the headset when powered on. Subsequently, when the headset is powered off, analytics agent 512 can record 11:00 AM as the time the headset is powered off and 70% as the battery level of the headset when powered off. Analytics agent 512 can then compute an energy consumption rate of the headset for the one hour duration from 10:00 AM to 11:00 AM to be 0.167% per minute (i.e., ((80%−70%)/(11:00 AM−10:00 AM))=0.167%/minute).

As another example, suppose that the same battery-operated headset is powered on again at 1:00 PM and powered off at 1:30 PM. Also suppose that the battery level of the headset is 70% when powered on and 63% when powered off. In this example, when the headset is powered on, analytics agent 512 can record 1:00 PM as the time the headset is powered on and 70% as the battery level of the headset when powered on. Subsequently, when the headset is powered off, analytics agent 512 can record 1:30 PM as the time the headset is powered off and 63% as the battery level of the headset when powered off. Analytics agent 512 can then compute an energy consumption rate of the headset for the 30 minute duration from 1:00 PM to 1:30 PM to be 0.233% per minute (i.e., ((70%−63%)+(1:30 PM −1:00 PM))=0.233%/minute).

Analytics agent 512 can utilize the computed energy consumption rates of a battery-operated device to compute an average daily energy consumption rate of the battery-operated device. The average daily energy consumption rate of the battery-operated device is the energy consumption rates of the battery-operated device averaged over a period of one day (i.e., 24 hours). Analytics agent 512 can compute the average daily energy consumption rate of the battery-operated device using the following algorithm:

$$U = {\sum }_{k = 0}^{n} \frac{{u}_{k} + {u}_{k - 1} + … + {u}_{n}}{n - k} ,$$

where u is an energy consumption rate for a duration, n is the number of computed energy consumption rates during the preceding period of one day, and U is the per minute average daily energy consumption rate.

As an example of computing an average daily energy consumption rate of a battery-operated device, suppose that the energy consumption rates computed in the past day for a battery-operated digital pen are as shown in Table 1.

TABLE 1

| | | | Energy |
|---|---|---|---|
| Power On | Power Off | | Consumption |
| Time | Time | Duration | Rate |
| 9:00 AM | 10:00 AM | 60 min | .167% |
| 1:30 PM | 2:00 PM | 30 min | .233% |
| 3:00 PM | 3:30 PM | 30 min | .167% |

In the example of Table 1, analytics agent 512 can compute the average daily energy consumption rate of the battery-operated digital pen to be 0.189% per minute (i.e., ((0.167%+0.233%+0.167%)+3)=0.189%/minute).

Analytics agent 512 can send or otherwise upload the computed average daily energy consumption rates of the individual battery-operated devices which were connected to client device 502 to load analysis service 510 where it can be stored for later use (e.g., used to compute a required battery level for a battery-operated device). For example, analytics agent 512 can send the computed average daily energy consumption rates of the individual battery-operated devices to load analysis service 510 at a predetermined time (e.g., 5:00 PM) each day or each working day. The time at which analytics agent 512 sends such data and information can be configured as an organizational policy or a user preference. Analytics agent 512 can also locally store the computed average daily energy consumption rates of the individual battery-operated devices.

In some embodiments, analytics agent 512 can determine an actual battery level of a battery-operated device connected to client device 502 in response to client device 502 receiving a request for a current battery level of a battery-operated device. The request can include a unique identifier of a battery-operated device for which the actual battery level determination is being requested. For example, load analysis service 510 may send a request to client device 502 for a current battery level of a battery-operated device. In response to LAS client 516 on client device 502 receiving such a request, analytics agent 512 can determine an actual battery level of the specified battery-operated device and send or otherwise provide the actual battery level of the specified battery-operated device in a response to the request.

Still referring to the client-side device management agent 508, charge notification module 514 is operable to provide a notification of a need to charge a battery-operated device. The notification, for example, may be displayed on a display of client device 502 for viewing by a user. For example, in one embodiment, charge notification module 514 can send a message to load analysis service 510 inquiring as to whether there is a need to notify a user to charge a battery-operated device associated with the user. In some embodiments, charge notification module 514 can send such inquiries to load analysis service 510 at predetermined times (e.g., 11:00 AM and 4:00 PM) each day or each working day. The time at which charge notification module 514 is to send such inquiries to load analysis service 514 can be configured as an organizational policy or a user preference. In response to sending such an inquiry, charge notification module 514 may receive a request to display a notification of a need to charge a battery-operated device and, in response, charge notification module 514 can render/display a notification that the battery-operated device needs to be charged. For example, charge notification module 514 can organize the information about the battery-operated device which needs to be charged into a data format that can be rendered/displayed as a UI or as part of a UI on a display of client device 502. Such information may include, for example, a unique identifier of the battery-operated device, an actual battery level of the battery-operated device, a required battery level for the battery-operated device, and details about any scheduled tasks that include the use or planned use of the battery-operated device, among others. Such information may be included or otherwise provided with the request to display a notification of a need to charge a battery-operated device.

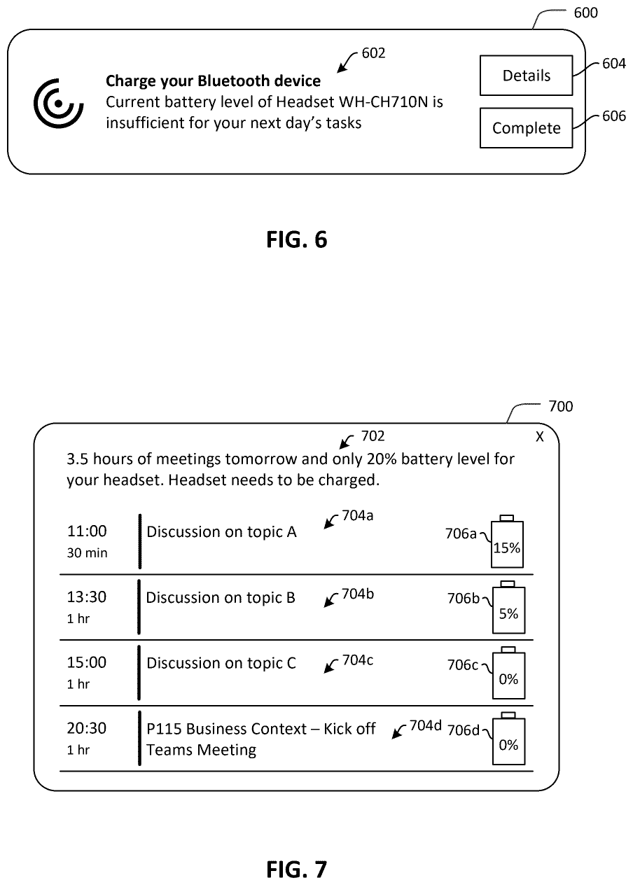

In one embodiment, charge notification module 514 can organize the information using various UI elements within a UI to notify a user of the need to charge the battery-operated device as well as enable the user to obtain further details as to why the battery-operated device needs charging. Charge notification module 514 can also include a button or other UI element for generating a confirmation of the charging of the battery-operated device. For example, the user can click/tap on such a button to send a confirmation that the user has viewed the notification and that the user intends to charge the battery-operated device. Examples of UIs that can be provided and/or displayed by charge notification module 514 are shown and further described below with respect to FIGS. 6 and 7.

In some embodiments, charge notification module 514 can provide a reminder notification of a need to charge a battery-operated device. The reminder notification, for example, on a display of mobile device associated with the user. In one embodiment, when charge notification module 514 renders/displays a notification that a battery-operated device needs to be charged, charge notification module 514 can determine whether a confirmation of the charging of the battery-operated device is received. As described above, the UI displaying the notification may include a UI element for generating a confirmation of the charging of the battery-operated device. If the user closes the notification UI without generating a confirmation, charge notification module 514 can determine that a confirmation of the charging of the battery-operated device will not be received. In such cases, charge notification module 514 can obtain an identity of another managed device, such as a mobile device, associated with the user from the organization's EMM system. Charge notification module 514 can then cause a reminder notification that the battery-operated device needs to be charged to be rendered/displayed within a UI on the other device associated with the user. For example, in one implementation, charge notification module 514 can send a reminder notification request to the user's other device that causes the other device to render/display a reminder notification that the battery-operated device needs to be charged within a UI on the other device.

In the embodiment of FIG. 5, device management agent 508 is shown as a component of resource access application 502. Thus, for example, UI elements provided by charge notification module 514 may be accessed within resource access application 502 (e.g., accessed within a UI of resource access application 502). In other embodiments, device management agent 508 may be implemented as a plug-in or component of another client application on client device 502. In still other embodiments, device management agent 508 may be implemented as a separate or standalone application on client device 502.

Referring to the cloud-side load analysis service 510, energy consumption rate processing module 520 is operable to process the average daily energy consumption rates of battery-operated devices sent or otherwise uploaded by device management agents 508. For example, when an average daily energy consumption rate of a battery-operated device is received by load analysis service 510, energy consumption rate processing module 520 can record the received information in a 3-tuple, which includes an identifier that uniquely identifies the battery-operated device (“Device_Name”), a date that the average daily energy consumption rate of the identified battery-operated device is uploaded to load analysis service 510 (“Upload_Date”), and an average daily energy consumption rate of the identified battery-operated device (“Minute_Level_Battery_Consumption”). Energy consumption rate processing module 520 can store the n-tuples corresponding to the average daily energy consumption rates of the battery-operated devices within data repository 522 that can correspond to, for example, a storage service within cloud computing environment 506.

In some embodiments, energy consumption rate processing module 520 can also store information about which users are associated with each of the battery-operated devices. For example, for a particular battery-operated device, energy consumption rate processing module 520 can obtain an identity of a user associated with the battery-operated device from the device management system (e.g., EMM system) utilized by the organization to manage the battery-operated device.

Energy consumption rate processing module 520 can use the recorded (e.g., collected) average daily energy consumption rate data to compute energy consumption rates of the individual battery-operated devices. In some embodiments, for a particular battery-operated device, energy consumption rate processing module 520 can compute an energy consumption rate of the battery-operated device by averaging the most recent N (e.g., N=10) average daily energy consumption rates of the battery-operated device. For example, if average daily energy consumption rates of a battery-operated device are recorded for August 1^{st} to August 30^{th}, an energy consumption rate can be computed by averaging the average daily energy consumption rates recorded for the most recent 10 days, which would be the average daily energy consumptions rates recorded for August 21^{st} to August 30^{th}. The value of N may be configurable by the organization and/or the user. It is appreciated that using recent average daily energy consumption rate data accounts for the likely degradation of battery capacity over time and provides a more accurate measure of the energy consumption rate of a battery-operated device.

In some embodiments, energy consumption rate processing module 520 can compute the energy consumption rates for the battery-operated devices on a continuous or periodic basis. For example, energy consumption rate processing module 520 can compute an energy consumption rate for the individual battery-operated devices according to a predetermined schedule such as, for example, at a specified time (e.g., 11:00 PM) each day. The time at which energy consumption rate processing module 520 can compute the energy consumption rates can be configured as an organizational policy or a user preference. Energy consumption rate processing module 520 can store the energy consumption rates computed for the individual battery-operated devices within data repository 522, where they can subsequently be retrieved and used to compute required battery levels for battery-operated devices.

Still referring to the cloud-side load analysis service 510, load analysis module 524 can utilize energy consumption rates computed for battery-operated devices to determine whether there is a need to charge the battery-operated devices. As described previously, charge notification module 514 on a client device (e.g., client device 502) may send a message to load analysis service 510 inquiring as to whether there is a need to notify a user to charge a battery-operated device associated with the user. In some embodiments, in response to such an inquiry being received by load analysis service 510, load analysis module 524 can collect/retrieve information about tasks scheduled for the user (or “the user's scheduled tasks”) from a task management application 526. Task management application 526 may correspond to the organization's task management application such as WRIKE, JIRA, and TRELLO, for example. Load analysis module 524 may utilize an API, such as a Representational State Transfer (REST)-based API, provided by task management application 526 to collect/retrieve the items of information therefrom.

The collected information about the user's scheduled tasks may include information about any battery-operated devices associated with the scheduled tasks. For example, when the user creates a first task, the user can indicate an intent to use a digital pen while performing the first task as part of the task information. As another example, when the user creates a second task, the user can indicate an intent to use a digital pen and VR goggles while performing the second task as part of the task information. In any case, from the retrieved information about a particular task scheduled for the user, load analysis module 524 can determine a length or duration of the scheduled task and any battery-operated devices associated with the scheduled task. For a given battery-operated device associated with a scheduled task, load analysis module 524 can retrieve the device's energy consumption rate from data repository 522 and compute a battery level that is required to use the battery-operated device while performing the scheduled task. For example, suppose that a scheduled task is for a duration of 60 minutes, a digital pen is associated with the task, and the digital pen's energy consumption rate is 0.167% per minute. In this example, a battery level of 10.02% (0.167%×60=10.02%) is required to use the digital pen while performing the scheduled task.

In some embodiments, load analysis module 524 can collect information about tasks scheduled for the user in a time period. That is to say, load analysis module 524 can collect information about the user's tasks that are scheduled in a time period. The time period may depend on when the inquiry is received by load analysis service 510. For example, if the inquiry is received in the morning (e.g., 11:00 AM), load analysis module 524 can collect information about tasks scheduled for the user during the afternoon (e.g., the time period is the afternoon of the same day). If the inquiry is received in the afternoon (e.g., 5:00 PM), load analysis module 524 can collect information about tasks scheduled for the user during the next day or next working day (e.g., the time period is the next day or next working day). In any case, form the collected information, load analysis module 524 can determine the battery-operated devices associated with the user's scheduled tasks and, for each determined battery-operated device, determine a length of time the battery-operated device is intended to be used by the user during the time period. That is, load analysis module 524 can determine a length of time the battery-operated device will be powered on during the afternoon if the inquiry is received in the morning or determine a length of time the battery-operated device will be powered on during the nest day if the inquiry is received in the afternoon. As an example of determining a length of time the battery-operated device will be powered on, if a battery-operated device is associated with a 60 minute task, a 30 minute task, and a 45 minute task, a length of time the battery-operated device will be powered on can be determined to be 135 minutes (60 minutes+30 Minutes+45 minutes=135 minutes). Load analysis module 524 can then compute a required battery level for the battery-operated device based on the length of time the battery-operated device will be powered on in the time period and the battery-operated device's energy consumption rate. Continuing the above example, if the battery-operated device's energy consumption rate is 0.233% per minute, load analysis module 524 can compute a required battery level of 31.455% (0.233%×135=31.455%) for the battery-operated device to be powered on for 135 minutes. In other words, a battery level of 31.455% is required to use the battery-operated device while performing the three scheduled tasks.

For a given battery-operated device associated with one or more tasks scheduled for the user in the time period, load analysis module 524 can determine whether there is a need to charge the battery-operated device based on an actual battery level of the battery-operated device and the required battery level for the battery-operated device (e.g., the battery level required for the battery-operated device to be powered on for the duration of the scheduled tasks associated with the battery-operated device). To determine the actual battery level of the battery-operated device, in one embodiment, load analysis module 524 can send a request to the user's client device (e.g., client device 502) for a current battery level of the battery-operated device. In response, load analysis module 524 can receive a response which includes an actual battery level of the battery-operated device. Load analysis module 524 can then determine whether there is a need to charge the battery-operated device based on a comparison of the actual battery level of the battery-operated device and the required battery level for the battery-operated device. For example, if the actual battery level of the battery-operated device is less (e.g., lower) than the required battery level, load analysis module 524 can send a request to the user's client device (e.g., client 502) to display a notification of a need to charge a battery-operated device. The request to display a notification of a need to charge a battery-operated device can be sent in a response to the inquiry received from charge notification module 514 on the client device. In some embodiments, the request to display a notification of a need to charge a battery-operated device can include, for example, a unique identifier of the battery-operated device which needs to be charged, an actual battery level of the battery-operated device, a required battery level for the battery-operated device, and details about any scheduled tasks that include the use or planned use of the battery-operated device.

In some embodiments, load analysis module 524 can determine whether there is a need to charge the battery-operated devices which are continuously powered on. For example, unlike battery-operated devices that are powered on periodically such as when a user is using a battery-operated device while performing specific tasks, certain battery-operated devices, such as a mouse, a keyboard, and the like, may be continuously powered on during the day. Such devices are referred to herein as “continuously powered battery-operated devices.” For continuously powered battery-operated devices, load analysis module 524 can utilize energy consumption rates computed for the continuously powered battery-operated devices to determine whether there is a need to charge the continuously powered battery-operated devices. In some embodiments, for a particular continuously powered battery-operated device, load analysis module 524 can determine a required battery level for the continuously powered battery-operated device based on the remaining time in the day and the continuously powered battery-operated device's energy consumption rate. Load analysis module 524 can then determine whether there is a need to charge the continuously powered battery-operated device based on an actual battery level of the continuously powered battery-operated device and the required battery level for the continuously powered battery-operated device. For example, suppose that there are six hours (360 minutes) remaining in the day, that the continuously powered battery-operated device's energy consumption rate is 0.125% per minute, and that the actual battery level of the continuously powered battery-operated device is 75%. In this example, load analysis module 524 can compute a required battery level of 31.455% (0.125%×360=45%) for the continuously powered battery-operated device to be powered on for the 360 minutes remaining in the day. Load analysis module 524 can also conclude that there is no need charge the continuously powered battery-operated device since the device's actual battery level is greater than the device's required battery level. In this example case, load analysis module 524 does not send a request to the user's client device (e.g., client 502) to display a notification of a need to charge the continuously powered battery-operated device.

While only a single task management application 526 is shown in the example of FIG. 5, in some cases load analysis module 524 may collect information about scheduled for the user from multiple different task management applications including calendaring services. The particular task management application and/or calendaring service from which load analysis module 524 collects task information can vary between different organizations and/or between different users of the same organization. To determine which task management applications and/or calendaring services to use for collecting task information, load analysis module 524 can obtain a list of applications and services used by a particular organization and/or user. For example, load analysis module 524 may obtain a list of subscribed resources (e.g., applications and services) for a particular user/organization via resource feed service 420 of FIG. 4B.

In other embodiments, the disclosed structure and/or functionality of load analysis service 510 may be implemented in whole or in part on a client device. For example, the structure/functionality of load analysis service 510 and/or one or more components of load analysis service 510 may be implemented as part of a client application (e.g., device management agent 508) and/or within a client device (e.g., within client device 502).

FIG. 6 shows an example of a user interface (UI) 600 for presenting a notification of a need to charge a battery-operated device, in accordance with an embodiment of the present disclosure. Illustrative UI 600 may be implemented within a client application, such as resource access application 504 of FIG. 5. In the example of FIG. 6, charge notification module 514 of FIG. 5 may render/display UI 600 to notify a user of a need to charge a battery-operated device.

As shown in FIG. 6, the illustrative UI 600 can include a notification display 602, a “Details” UI element 604, and a “Complete” UI element 606. Notification display 602 can show information about a battery-operated device that needs charging. In the example of FIG. 6, the content of notification display 602 is informing a user to “Charge your Bluetooth device” and that the “Current battery level of Headset WH-CH710N is insufficient for your next day's tasks.” UI element (e.g., a button) 604 can be used to obtain additional details as to why the battery-operated device identified in notification display 602 (e.g., Headset WH-CH710N) needs charging. For example, in response to a user clicking or tapping UI element 604, UI 600 can cause another UI to be rendered/displayed which displays the additional information. For example, as will be further described below with respect to the example of FIG. 7, the rendered/displayed UI can show information about the user's scheduled tasks associated with the battery-operated device (e.g., show information about the scheduled tasks in which the user intends to use the battery-operated device), and the battery level required for each of the scheduled tasks. UI element (e.g., a button) 606 can be used to confirm the charging of the battery-operated device identified in notification display 602 (e.g., Headset WH-CH710N). For example, in response to the user clicking or tapping UI element 606, UI 600 can cause a confirmation of the charging of the battery-operated device to be sent or otherwise provided to charge notification module 514.

Turning to FIG. 7 and with continued reference to FIG. 6, shown is an example of a user interface (UI) 700 for presenting additional details regarding a notification of a need to charge a battery-operated device, in accordance with an embodiment of the present disclosure. Illustrative UI 700 may be implemented within a client application, such as resource access application 504 of FIG. 5. In the example of FIG. 7, charge notification module 514 of FIG. 5 may render/display UI 700 in response to the user clicking or tapping UI element 604 within UI 600, as described in the example of FIG. 6 above.

As shown in FIG. 7, the illustrative UI 700 can include an additional information display 702. Information display 702 can show additional details as to why the battery-operated device identified in notification display 602 within UI 600 needs charging. In the example of FIG. 7, the content of information display 702 is informing the user of “3.5 hours of meetings tomorrow and only 20% battery level for your headset.” The content of information display 702 is also informing the user that the “Headset needs to be charged.” Some or all the information displayed within information display 702 can be obtained from and/or provided by load analysis service 510.

UI 700 can also include information displays 704a, 704b, 704c, and 704d (704 generally) which show information about the user's scheduled tasks associated with the battery-operated device. The scheduled tasks shown in information displays 704 correspond to the 3.5 hours of meetings indicated in information display 702. In the example of FIG. 7, information display 704a shows that the user is scheduled to attend a 30 minute meeting scheduled to start at 11:00 (“Discussion on topic A”). Information display 704b shows that the user is scheduled to attend a one hour meeting scheduled to start at 13:30 (“Discussion on topic B”). Information display 704c shows that the user is scheduled to attend a one hour meeting scheduled to start at 15:00 (“Discussion on topic C”). Information display 704d shows that the user is scheduled to attend a one hour meeting scheduled to start at 20:30 (“P115 Business Context—Kick off Teams Meeting”).

For each of the displayed information displays 704, UI 700 can also include an icon (e.g., a battery) which indicates an estimated battery level of the battery-operated device at the start of the corresponding scheduled task shown in the information display 704. The estimated battery level of the battery-operated device is based on an actual battery level of the battery-operated device, an energy consumption rate computed for the battery-operated device, and an expected usage of the battery-operated device (e.g., an estimate of the time the battery-operated device is to be powered on). In one embodiment, the displayed icons may be color coded to indicate whether the estimated battery level of the battery-operated device is sufficient for the duration of the corresponding scheduled task. In the example of FIG. 7, information display 704a can include an icon 706a which indicates a 15% estimated battery level of the headset at the beginning of the 30 minute meeting scheduled to start at 11:00. Additionally, icon 706a may be colored green to indicate the 15% estimated battery level is sufficient to power the headset for the duration of the 30 minute meeting scheduled to start at 11:00. Information display 704b can include an icon 706b which indicates a 5% estimated battery level of the headset at the beginning of the one hour meeting scheduled to start at 13:30. Additionally, icon 706b may be colored yellow to indicate the 5% estimated battery level may not be sufficient to power the headset for the duration of the one hour meeting scheduled to start at 13:30. Information display 704c can include an icon 706c which indicates a 0% estimated battery level of the headset at the beginning of the one hour meeting scheduled to start at 15:00. Additionally, icon 706c may be colored red to indicate the 0% estimated battery level is not sufficient to power the headset for the duration of the one hour meeting scheduled to start at 15:00. Information display 704d can include an icon 706d which indicates a 0% estimated battery level of the headset at the beginning of the one hour meeting scheduled to start at 20:30. Additionally, icon 706d may be colored red to indicate the 0% estimated battery level is not sufficient to power the headset for the duration of the one hour meeting scheduled to start at 20:30. Some or all of the information displayed within information displays 704 can be obtained from and/or provided by load analysis service 510.

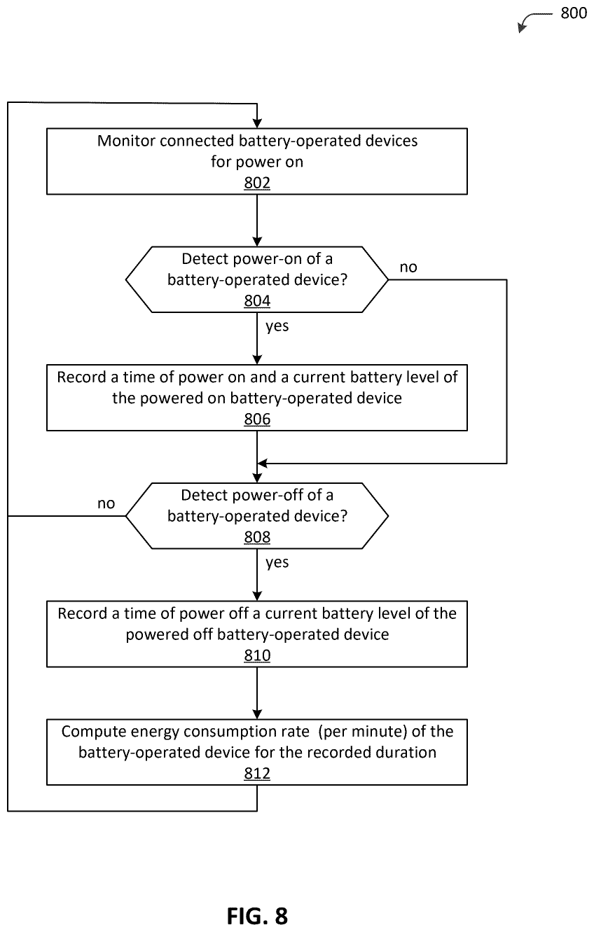

FIG. 8 is a flow diagram of an illustrative process 800 for computing an energy consumption rate of a battery-operated device for a recorded duration, in accordance with an embodiment of the present disclosure. Illustrative process 800 may be implemented, for example, within a device management agent (e.g., device management agent 508 of FIG. 5) on a computing device associated with a user, such as client device 502 of FIG. 5.

Referring to process 800, at 802, battery-operated devices connected to the computing device are monitored for powered on. For example, the OS on the client device can be utilized to discover battery-operated devices connected to the client device. The discovered battery-operated devices can then be monitored for power on and power off.

At 804, a check can be made as to whether a power on of a battery-operated device is detected. If a power on of a battery-operated device is detected, then, at 806, a time of power on of the battery-operated device and a current battery level of the powered on battery-operated device are recorded. The recorded time of power on of the battery-operated device can be the time that the power on of the battery-operated device is detected. The recorded current battery level of the battery-operated device can be the battery level of the battery-operated device at or proximate the time the battery-operated device is powered on. For example, an API provided by the OS on the client device can be utilized to determine the current battery level of the powered on battery-operated device.

Otherwise, if a power on of a battery-operated device is not detected or subsequent to recording the time of power on and the current battery level of the battery-operated device at 806, at 808, a check can be made as to whether a power off of a battery-operated device is detected. If a power off of a battery-operated device is not detected, then, at 802, monitoring of the battery-operated devices connected to the computing device can be continued.

Otherwise, if a power off of a battery-operated device is detected, then, at 810, a time of the power off of the battery-operated device and a current battery level of the powered off battery-operated device are recorded. The recorded time of the power off of the battery-operated device can be the time that the power off of the battery-operated device is detected. The recorded current battery level of the battery-operated device can be the battery level of the battery-operated device at or proximate the time the battery-operated device is powered off. For example, an API provided by the OS on the client device can be utilized to determine the current battery level of the powered off battery-operated device.

At 812, an energy consumption rate (e.g., a per minute energy consumption rate) of the battery-operated device for the recorded duration is computed. The recorded duration is from the recorded time of power on of the battery-operated device to the recorded time of the power off of the battery-operated device. The energy consumption rate of the battery-operated device for the recorded duration can be computed based on the recorded power on and power off times and the respective recorded current battery levels of the battery-operated device at these times, as previously described herein.

Subsequent to computing an energy consumption rate of a battery-operated device for a recorded duration, at 802, monitoring of the battery-operated devices connected to the computing device can be continued.

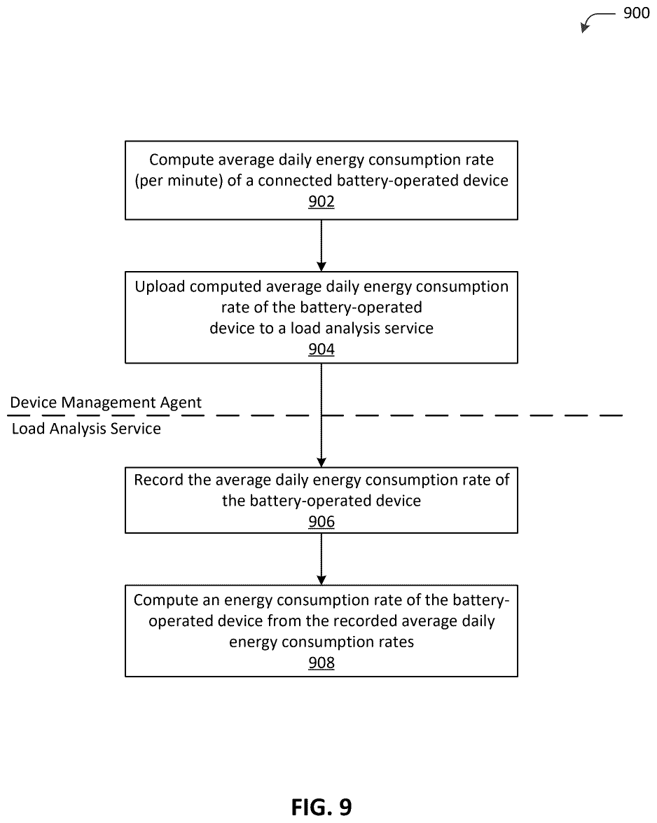

FIG. 9 is a flow diagram of an illustrative process 900 for computing an energy consumption rate of a battery-operated device, in accordance with an embodiment of the present disclosure. Illustrative process 900 may be implemented, for example, within a device management agent (e.g., device management agent 508 of FIG. 5) on a computing device associated with a user, such as client device 502 of FIG. 5, and/or a load analysis service (e.g., load analysis service 510 of FIG. 5).

Referring to process 900, on the client device, at 902, an average daily energy consumption rate (e.g., a per minute average daily energy consumption rate) of a connected battery-operated device is computed. The average daily energy consumption rate of the battery-operated device is an average of the energy consumption rates computed for the battery-operated device over a period of one day (e.g., past 24 hours).

At 902, the computed average daily energy consumption rate of a battery-operated device is uploaded to the load analysis service. For example, the average daily energy consumption rate can be uploaded at a predetermined time each day. Note that average daily energy consumption rates can be computed for one or more battery-operated devices (e.g., the battery-operated devices which were connected to the client device), and the computed average daily energy consumption rates can be upload to the load analysis service.

On the load analysis service, at 906, the uploaded average daily energy consumption rate of a battery-operated device is recorded. For example, the average daily energy consumption rate of the battery-operated device can be recorded in a 3-tuple (e.g., a 3-tuple of an identifier that uniquely identifies the battery-operated device, a date that the average daily energy consumption rate of the identified battery-operated device is uploaded, and an average daily energy consumption rate). The 3-tuple can then be stored within a data repository (e.g., data repository 522 of FIG. 5).

At 908, an energy consumption rate of the battery-operated device is computed. The energy consumption rate of the battery-operated device can be computed based on the recorded average daily energy consumption rates of the battery-operated device, as previously described herein. The energy consumption rate of the battery-operated device can be computed on a continuous or periodic bases, such as, for example, once each day. The computed energy consumption rate of the battery-operated device can be stored within the data repository. Note that energy consumption rates can be computed for one or more battery-operated devices, and the computed energy consumption rates can be stored within the data repository.

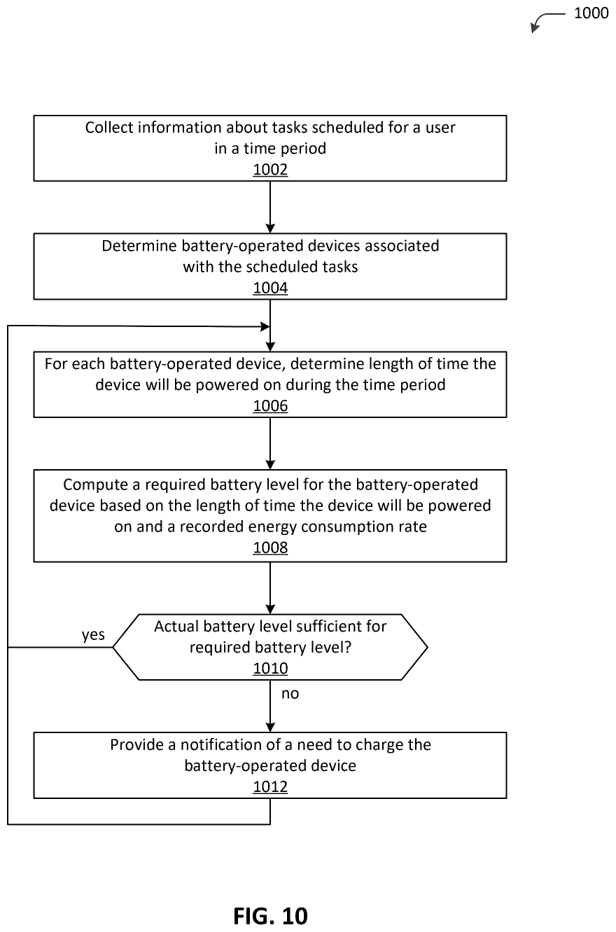

FIG. 10 is a flow diagram of an illustrative process 1000 for determining whether a battery-operated device requires charging based on scheduled tasks, in accordance with an embodiment of the present disclosure. Illustrative process 1000 may be implemented, for example, within a load analysis service (e.g., load analysis service 510 of FIG. 5). In the following description, it is assumed that an inquiry as to whether there is a need to notify a user to charge a battery-operated device associated with the user is received from a client device (e.g., client device 502 of FIG. 5). In the example of FIG. 10, the battery-operated device may be a device that is powered on periodically such as when the user is using the battery-operated device while performing specific tasks. In other words, the battery-operated device is not a continuously powered battery-operated device.

Referring to process 1000, at 1002, information about tasks scheduled for the user in a time period is collected. The time period may depend on when the inquiry is received from the client device and may be, for example, a remaining time in the same day or a time in a next day. For example, the information about the tasks scheduled for the user in a time period can be collected from a task management system (e.g., task management system 526 of FIG. 5).

At 1004, any battery-operated devices that are associated with the tasks scheduled for the user is determined (e.g., ascertained). For example, the battery-operated devices that are associated with the tasks scheduled for the user can be ascertained from the collected information about the user's scheduled tasks since this information includes information about any battery-operated devices associated with the scheduled tasks.

At 1006, for each battery-operated device ascertained at 1004, a length of time the battery-operated device will be powered on during the time period is determined. The length of time a battery-operated device will be powered on can be determined based on the durations of the user's scheduled tasks associated with the battery-operated device.

At 1008, a required battery level for the battery-operated device is computed. The required battery level for the battery-operated device can be computed based the length of time the battery-operated device will be powered on in the time period and the energy consumption rate of the battery-operated device. For example, the energy consumption rate of the battery-operated device can be retrieved from the data repository (e.g., data repository 522 of FIG. 5).

At 1010, a check can be made to determine whether an actual battery level of the battery-operated device is sufficient for the required battery level for the battery-operated device (e.g., check to determine whether the actual battery level is more (e.g., higher) than the required battery level). For example, the actual battery level of the battery-operated device can be obtained from the client device. If it is determined that the actual battery level of the battery-operated device is sufficient for the required battery level for the battery-operated device, a notification of a need to charge the battery-operated device is not provided. In this case, at 1006, another battery-operated device that is associated with the tasks scheduled for the user can be processed to determine whether the user needs to be notified to charge the another battery-operated device.

Otherwise, if it is determined that the actual battery level of the battery-operated device is not sufficient for the required battery level for the battery-operated device, then, at 1012, a notification of a need to charge the battery-operated device is provided. For example, a request to display a notification of a need to charge a battery-operated device can be sent or otherwise provided to the client device. In response to receiving such request, the client device can render/display a notification that the battery-operated device needs to be charged within a UI on the client device.

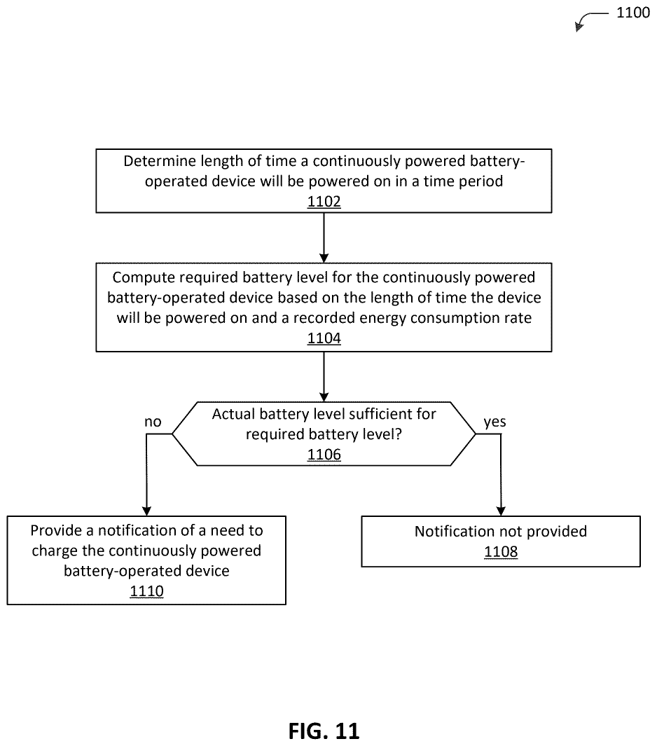

FIG. 11 is a flow diagram of an illustrative process 1100 for determining whether a battery-operated device requires charging, in accordance with an embodiment of the present disclosure. Illustrative process 1100 may be implemented, for example, within a load analysis service (e.g., load analysis service 510 of FIG. 5). In the following description, it is assumed that an inquiry as to whether there is a need to notify a user to charge a battery-operated device associated with the user is received from a client device (e.g., client device 502 of FIG. 5). In the example of FIG. 11, the battery-operated device may be a continuously powered battery-operated device.

Referring to process 1100, at 1102, a length of time the continuously powered battery-operated device will be powered on in a time period is determined. The time period may be a remaining time in the day (e.g., the time remaining in the day subsequent to receipt of the inquiry from the computing device). The length of time the continuously powered battery-operated device will be powered on is the remaining time in the day (e.g., the time period) since the battery-operated device is a continuously powered battery-operated device.

At 1104, a required battery level for the continuously powered battery-operated device is computed. The required battery level for the continuously powered battery-operated device can be computed based the length of time the continuously powered battery-operated device will be powered on and the energy consumption rate of the continuously powered battery-operated device. For example, the energy consumption rate of the continuously powered battery-operated device can be retrieved from the data repository (e.g., data repository 522 of FIG. 5).

At 1106, a check can be made to determine whether an actual battery level of the continuously powered battery-operated device is sufficient for the required battery level for the continuously powered battery-operated device (e.g., check to determine whether the actual battery level is more (e.g., higher) than the required battery level). For example, the actual battery level of the continuously powered battery-operated device can be obtained from the client device. If it is determined that the actual battery level of the continuously powered battery-operated device is sufficient for the required battery level for the continuously powered battery-operated device, a notification of a need to charge the continuously powered battery-operated device is not provided. In this case, another continuously powered battery-operated device that is associated with the user can be ascertained and processed to determine whether the user needs to be notified to charge the another continuously powered battery-operated device.

Otherwise, if it is determined that the actual battery level of the continuously powered battery-operated device is not sufficient for the required battery level for the continuously powered battery-operated device, then, at 1108, a notification of a need to charge the continuously powered battery-operated device is provided. For example, a request to display a notification of a need to charge a battery-operated device can be sent or otherwise provided to the client device. In response to receiving such request, the client device can render/display a notification that the continuously powered battery-operated device needs to be charged within a UI on the client device.

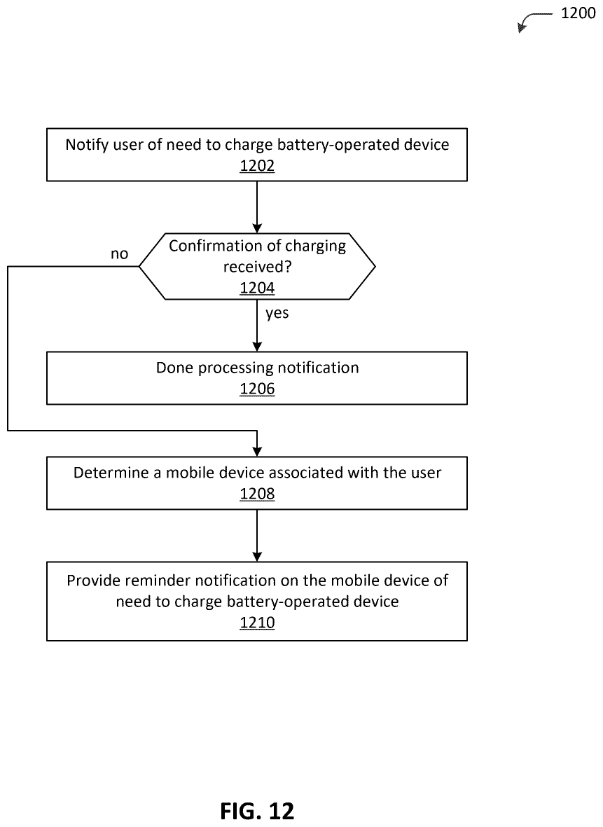

FIG. 12 is a flow diagram of an illustrative process 1200 for providing a reminder notification of a need to charge a battery-operated device, in accordance with an embodiment of the present disclosure. Illustrative process 1200 may be implemented, for example, within a device management agent (e.g., device management agent 508 of FIG. 5) on a computing device associated with a user, such as client device 502 of FIG. 5. In some embodiments, at least a portion of process 1200 may be implemented within a server device (e.g., load analysis service 510 of FIG. 5).

Referring to process 1200, at 1202, a user of the computing device is notified of a need to charge a battery-operated device. For example, a notification to charge the battery-operated device can be rendered/displayed within a UI on a display of the computing device.

At 1204, a check can be made to determine whether a confirmation of the charging of the battery-operated device is received. For example, the displayed notification can include a UI element that the user can click or tap to generate a confirmation of the charging of the battery-operated device. If it is determined that a confirmation of the charging of the battery-operated device is received, then, at 1206, processing of the notification completes.

Otherwise, if it is determined that a confirmation of the charging of the battery-operated device is not received, then, at 1208, another computing device, such as a mobile device, associated with the user is determined. An identity of a mobile device associated with the user can be obtained, for example, from the organization's EMM system or other device management system which is being used to manage the user's devices. For example, the user may close the notification UI without generating a confirmation of the charging of the battery-operated device.

At 1210, a reminder notification of a need to charge the battery-operated device is provided on the mobile device associated with the user. For example, the reminder notification to charge the battery-operated device can be rendered/displayed within a UI on a display of the mobile device.

### FURTHER EXAMPLE EMBODIMENTS

The following examples pertain to further embodiments, from which numerous permutations and configurations will be apparent.

Example 1 includes a method including: collecting, by a computing device from one or more task management services, information about tasks scheduled for a user in a time period, the time period being later than a current time; determining, by the computing device, a battery-operated device associated with one of the tasks; determining, by the computing device, a length of time the battery-operated device will be powered on during the time period based on the information collected about the tasks; computing, by the computing device, a required battery level for the battery-operated device based on the length of time the battery-operated device will be powered on during the time period and an energy consumption rate of the battery-operated device; and, responsive to a determination that an actual battery level of the battery-operated device is less than the required battery level, providing, by the computing device, a notification of a need to charge the battery-operated device.

Example 2 includes the subject matter of Example 1, wherein the battery-operated device includes a Bluetooth device.

Example 3 includes the subject matter of any of Examples 1 and 2, wherein the time period is a next working day.

Example 4 includes the subject matter of any of Examples 1 and 2, wherein the time period is a remaining time in a current day.

Example 5 includes the subject matter of any of Examples 1 through 4, wherein the determining the battery-operated device associated with one of the tasks is based on the information collected about the tasks.

Example 6 includes the subject matter of any of Examples 1 through 5, wherein the length of time the battery-operated device will be powered on during the time period is a length of the time period.

Example 7 includes the subject matter of any of Examples 1 through 5, wherein the length of time the battery-operated device will be powered on during the time period is a length of time of the tasks in the time period which are associated with the battery-operated device.

Example 8 includes the subject matter of any of Examples 1 through 7, wherein the energy consumption rate of the battery-operated device is over one or more durations the battery-operated device is powered on during a day.

Example 9 includes the subject matter of any of Examples 1 through 8, wherein the energy consumption rate of the battery-operated device is an average energy consumption rate.

Example 10 includes the subject matter of Example 9, wherein the average energy consumption rate of the battery-operated device is an average of most recent 10 average daily energy consumption rates of the battery-operated device.

Example 11 includes the subject matter of any of Examples 1 through 10, wherein the providing the notification including sending a request to another computing device to notify of a need to charge the battery-operated device.

Example 12 includes the subject matter of any of Examples 1 through 11, further including, responsive to receiving the request: displaying, by the another computing device, on a display of the another computing device a notice informing that the actual battery level of the battery-operated device is insufficient for the time period, wherein the notice includes a first user interface (UI) element that can be used to obtain details about the required battery level for the battery-operated device, and a second UI element that can be used to provide a confirmation of a charging of the battery-operated device.

Example 13 includes the subject matter of Example 12, further including, responsive to a determination that the confirmation of the charging of the battery-operated device is not received: determining, by the another computing device, a mobile device associated with the user; and causing, by the another computing device, the notice informing that the actual battery level of the battery-operated device is insufficient for the time period to display on the mobile device.

Example 14 includes the subject matter of any of Examples 1 through 13, wherein the providing the notification includes displaying, by the computing device, on a display of the computing device a notice informing that the actual battery level of the battery-operated device is insufficient for the time period, wherein the notice includes a first user interface (UI) element that can be used to obtain details about the required battery level for the battery-operated device, and a second UI element that can be used to provide a confirmation of a charging of the battery-operated device.

Example 15 includes a computing device including a processor and a non-volatile memory storing computer program code that when executed on the processor causes the processor to execute a process including: collecting, from one or more task management services, information about tasks scheduled for a user in a time period, the time period being later than a current time; determining a battery-operated device associated with one of the tasks; determining a length of time the battery-operated device will be powered on during the time period based on the information collected about the tasks; computing a required battery level for the battery-operated device based on the length of time the battery-operated device will be powered on during the time period and an energy consumption rate of the battery-operated device; and, responsive to a determination that an actual battery level of the battery-operated device is less than the required battery level, providing a notification of a need to charge the battery-operated device.

Example 16 includes the subject matter of Example 15, wherein the battery-operated device includes a Bluetooth device.

Example 17 includes the subject matter of any of Examples 15 and 16, wherein the time period is a next working day.

Example 18 includes the subject matter of any of Examples 15 and 16, wherein the time period is a remaining time in a current day.

Example 19 includes the subject matter of any of Examples 15 through 18, wherein the determining the battery-operated device associated with one of the tasks is based on the information collected about the tasks.

Example 20 includes the subject matter of any of Examples 15 through 19, wherein the length of time the battery-operated device will be powered on during the time period is a length of the time period.

Example 21 includes the subject matter of any of Examples 15 through 19, wherein the length of time the battery-operated device will be powered on during the time period is a length of time of the tasks in the time period which are associated with the battery-operated device.

Example 22 includes the subject matter of any of Examples 15 through 21, wherein the energy consumption rate of the battery-operated device is over one or more durations the battery-operated device is powered on during a day.

Example 23 includes the subject matter of any of Examples 15 through 22, wherein the energy consumption rate of the battery-operated device is an average energy consumption rate.

Example 24 includes the subject matter of Example 23, wherein the average energy consumption rate of the battery-operated device is an average of most recent 10 average daily energy consumption rates of the battery-operated device.

Example 25 includes the subject matter of any of Examples 15 through 24, wherein the providing the notification including sending a request to another computing device to notify of a need to charge the battery-operated device.

Example 26 includes the subject matter of any of Examples 15 through 25, wherein the process also including, responsive to receiving the request: displaying, by the another computing device, on a display of the another computing device a notice informing that the actual battery level of the battery-operated device is insufficient for the time period, wherein the notice includes a first user interface (UI) element that can be used to obtain details about the required battery level for the battery-operated device, and a second UI element that can be used to provide a confirmation of a charging of the battery-operated device.

Example 27 includes the subject matter of Example 26, wherein the process further including, responsive to a determination that the confirmation of the charging of the battery-operated device is not received: determining, by the another computing device, a mobile device associated with the user; and causing, by the another computing device, the notice informing that the actual battery level of the battery-operated device is insufficient for the time period to display on the mobile device.

Example 28 includes the subject matter of any of Examples 15 through 27, wherein the providing the notification includes displaying on a display of the computing device a notice informing that the actual battery level of the battery-operated device is insufficient for the time period, wherein the notice includes a first user interface (UI) element that can be used to obtain details about the required battery level for the battery-operated device, and a second UI element that can be used to provide a confirmation of a charging of the battery-operated device.

Example 29 includes a non-transitory machine-readable medium encoding instructions that when executed by one or more processors cause a process to be carried out. The process includes: collecting, from one or more task management services, information about tasks scheduled for a user in a time period, the time period being later than a current time; determining a battery-operated device associated with one of the tasks; determining a length of time the battery-operated device will be powered on during the time period based on the information collected about the tasks; computing a required battery level for the battery-operated device based on the length of time the battery-operated device will be powered on during the time period and an energy consumption rate of the battery-operated device; and, responsive to a determination that an actual battery level of the battery-operated device is less than the required battery level, providing a notification of a need to charge the battery-operated device.

Example 30 includes the subject matter of Example 29, wherein the battery-operated device includes a Bluetooth device.

Example 31 includes the subject matter of any of Examples 29 and 30, wherein the time period is a next working day.

Example 32 includes the subject matter of any of Examples 29 and 30, wherein the time period is a remaining time in a current day.

Example 33 includes the subject matter of any of Examples 29 through 32, wherein the determining the battery-operated device associated with one of the tasks is based on the information collected about the tasks.

Example 34 includes the subject matter of any of Examples 29 through 33, wherein the length of time the battery-operated device will be powered on during the time period is a length of the time period.

Example 35 includes the subject matter of any of Examples 29 through 33, wherein the length of time the battery-operated device will be powered on during the time period is a length of time of the tasks in the time period which are associated with the battery-operated device.

Example 36 includes the subject matter of any of Examples 29 through 35, wherein the energy consumption rate of the battery-operated device is over one or more durations the battery-operated device is powered on during a day.

Example 37 includes the subject matter of any of Examples 29 through 36, wherein the energy consumption rate of the battery-operated device is an average energy consumption rate.

Example 38 includes the subject matter of Example 37, wherein the average energy consumption rate of the battery-operated device is an average of most recent 10 average daily energy consumption rates of the battery-operated device.

Example 39 includes the subject matter of any of Examples 29 through 38, wherein the providing the notification including sending a request to another computing device to notify of a need to charge the battery-operated device.

Example 40 includes the subject matter of any of Examples 29 through 39, wherein the process also includes, responsive to receiving the request: displaying, by the another computing device, on a display of the another computing device a notice informing that the actual battery level of the battery-operated device is insufficient for the time period, wherein the notice includes a first user interface (UI) element that can be used to obtain details about the required battery level for the battery-operated device, and a second UI element that can be used to provide a confirmation of a charging of the battery-operated device.

Example 41 includes the subject matter of Example 40, wherein the process further includes, responsive to a determination that the confirmation of the charging of the battery-operated device is not received: determining, by the another computing device, a mobile device associated with the user; and causing, by the another computing device, the notice informing that the actual battery level of the battery-operated device is insufficient for the time period to display on the mobile device.

Example 42 includes the subject matter of any of Examples 29 through 41, wherein the providing the notification includes displaying on a display of the computing device a notice informing that the actual battery level of the battery-operated device is insufficient for the time period, wherein the notice includes a first user interface (UI) element that can be used to obtain details about the required battery level for the battery-operated device, and a second UI element that can be used to provide a confirmation of a charging of the battery-operated device.

As will be further appreciated in light of this disclosure, with respect to the processes and methods disclosed herein, the functions performed in the processes and methods may be implemented in differing order. Additionally or alternatively, two or more operations may be performed at the same time or otherwise in an overlapping contemporaneous fashion. Furthermore, the outlined actions and operations are only provided as examples, and some of the actions and operations may be optional, combined into fewer actions and operations, or expanded into additional actions and operations without detracting from the essence of the disclosed embodiments.

In the description of the various embodiments, reference is made to the accompanying drawings identified above and which form a part hereof, and in which is shown by way of illustration various embodiments in which aspects of the concepts described herein may be practiced. It is to be understood that other embodiments may be utilized, and structural and functional modifications may be made without departing from the scope of the concepts described herein. It should thus be understood that various aspects of the concepts described herein may be implemented in embodiments other than those specifically described herein. It should also be appreciated that the concepts described herein are capable of being practiced or being carried out in ways which are different than those specifically described herein.

As used in the present disclosure, the terms “engine” or “module” or “component” may refer to specific hardware implementations configured to perform the actions of the engine or module or component and/or software objects or software routines that may be stored on and/or executed by general purpose hardware (e.g., computer-readable media, processing devices, etc.) of the computing system. In some embodiments, the different components, modules, engines, and services described in the present disclosure may be implemented as objects or processes that execute on the computing system (e.g., as separate threads). While some of the system and methods described in the present disclosure are generally described as being implemented in software (stored on and/or executed by general purpose hardware), specific hardware implementations, firmware implements, or any combination thereof are also possible and contemplated. In this description, a “computing entity” may be any computing system as previously described in the present disclosure, or any module or combination of modulates executing on a computing system.

Terms used in the present disclosure and in the appended claims (e.g., bodies of the appended claims) are generally intended as “open” terms (e.g., the term “including” should be interpreted as “including, but not limited to,” the term “having” should be interpreted as “having at least,” the term “includes” should be interpreted as “includes, but is not limited to,” etc.).

Additionally, if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations.

In addition, even if a specific number of an introduced claim recitation is explicitly recited, such recitation should be interpreted to mean at least the recited number (e.g., the bare recitation of “two widgets,” without other modifiers, means at least two widgets, or two or more widgets). Furthermore, in those instances where a convention analogous to “at least one of A, B, and C, etc.” or “one or more of A, B, and C, etc.” is used, in general such a construction is intended to include A alone, B alone, C alone, A and B together, A and C together, B and C together, or A, B, and C together, etc.

It is to be understood that the phraseology and terminology used herein are for the purpose of description and should not be regarded as limiting. Rather, the phrases and terms used herein are to be given their broadest interpretation and meaning. The use of “including” and “comprising” and variations thereof is meant to encompass the items listed thereafter and equivalents thereof as well as additional items and equivalents thereof. The use of the terms “connected,” “coupled,” and similar terms, is meant to include both direct and indirect, connecting, and coupling.

All examples and conditional language recited in the present disclosure are intended for pedagogical examples to aid the reader in understanding the present disclosure, and are to be construed as being without limitation to such specifically recited examples and conditions. Although example embodiments of the present disclosure have been described in detail, various changes, substitutions, and alterations could be made hereto without departing from the spirit and scope of the present disclosure. Accordingly, it is intended that the scope of the present disclosure be limited not by this detailed description, but rather by the claims appended hereto.

What is claimed is:

1. A method comprising:
collecting, by a computing device from one or more task management services, information about tasks scheduled for a user in a time period, the time period being later than a current time;
determining, by the computing device, a battery-operated device associated with one of the tasks;
determining, by the computing device, a length of time the battery-operated device will be powered on during the time period based on the information collected about the tasks;
computing, by the computing device, a required battery level for the battery-operated device based on the length of time the battery-operated device will be powered on during the time period and an energy consumption rate of the battery-operated device; and
responsive to a determination that an actual battery level of the battery-operated device is less than the required battery level, providing, by the computing device, a notification of a need to charge the battery-operated device.

2. The method of claim 1, wherein the time period is a next working day.

3. The method of claim 1, wherein the time period is a remaining time in a current day.

4. The method of claim 1, wherein the determining the battery-operated device associated with one of the tasks is based on the information collected about the tasks.

5. The method of a claim 1, wherein the length of time the battery-operated device will be powered on during the time period is a length of the time period.

6. The method of a claim 1, wherein the length of time the battery-operated device will be powered on during the time period is a length of time of the tasks in the time period which are associated with the battery-operated device.

7. The method of claim 1, wherein the energy consumption rate of the battery-operated device is over one or more durations the battery-operated device is powered on during a day.

8. The method of claim 1, wherein the energy consumption rate of the battery-operated device is an average energy consumption rate.

9. The method of claim 8, wherein the average energy consumption rate of the battery-operated device is an average of most recent 10 average daily energy consumption rates of the battery-operated device.

10. The method of claim 1, wherein the providing the notification including sending a request to another computing device to notify of a need to charge the battery-operated device.

11. The method of claim 10, further comprising, responsive to receiving the request:
displaying, by the another computing device, on a display of the another computing device a notice informing that the actual battery level of the battery-operated device is insufficient for the time period, wherein the notice includes a first user interface (UI) element that can be used to obtain details about the required battery level for the battery-operated device, and a second UI element that can be used to provide a confirmation of a charging of the battery-operated device.

12. The method of claim 11, further comprising, responsive to a determination that the confirmation of the charging of the battery-operated device is not received:
determining, by the another computing device, a mobile device associated with the user; and
causing, by the another computing device, the notice informing that the actual battery level of the battery-operated device is insufficient for the time period to display on the mobile device.

13. The method of claim 1, wherein the providing the notification includes:
displaying, by the computing device, on a display of the computing device a notice informing that the actual battery level of the battery-operated device is insufficient for the time period, wherein the notice includes a first user interface (UI) element that can be used to obtain details about the required battery level for the battery-operated device, and a second UI element that can be used to provide a confirmation of a charging of the battery-operated device.

14. A computing device comprising:
a processor; and
a non-volatile memory storing computer program code that when executed on the processor causes the processor to execute a process including:
collecting, from one or more task management services, information about tasks scheduled for a user in a time period, the time period being later than a current time;
determining a battery-operated device associated with one of the tasks;
determining a length of time the battery-operated device will be powered on during the time period based on the information collected about the tasks;
computing a required battery level for the battery-operated device based on the length of time the battery-operated device will be powered on during the time period and an energy consumption rate of the battery-operated device; and
responsive to a determination that an actual battery level of the battery-operated device is less than the required battery level, providing a notification of a need to charge the battery-operated device.

15. The computing device of claim 14, wherein the time period is one of a next working day or a remaining time in a current day.

16. The computing device of claim 14, wherein the determining the battery-operated device associated with one of the tasks is based on the information collected about the tasks.

17. The computing device of claim 14, wherein the length of time the battery-operated device will be powered on during the time period is a length of the time period.

18. The computing device of claim 14, wherein the length of time the battery-operated device will be powered on during the time period is a length of time of the tasks in the time period which are associated with the battery-operated device.

19. The computing device of claim 14, wherein the average energy consumption rate of the battery-operated device is an average of most recent 10 average daily energy consumption rates of the battery-operated device.

20. A non-transitory machine-readable medium encoding instructions that when executed by one or more processors cause a process to be carried out, the process including:
collecting, from one or more task management services, information about tasks scheduled for a user in a time period, the time period being later than a current time;
determining a battery-operated device associated with one of the tasks;
determining a length of time the battery-operated device will be powered on during the time period based on the information collected about the tasks;
computing a required battery level for the battery-operated device based on the length of time the battery-operated device will be powered on during the time period and an energy consumption rate of the battery-operated device; and
responsive to a determination that an actual battery level of the battery-operated device is less than the required battery level, providing a notification of a need to charge the battery-operated device.
